(19) United States
(12) Patent Application Publication
(10) Pub. No.: US 2026/0333712 A1
(43) Pub. Date: Oct. 22, 2026

(54) NONVOLATILE MEMORY DEVICE INCLUDING SUB-PLANES

(71) Applicant: SAMSUNG ELECTRONICS CO., LTD., Suwon-si (KR)

(72) Inventors: Youngjae Kim, Suwon-si (KR); Jonguk Wi, Suwon-si (KR); Kyungmin Kang, Suwon-si (KR); Junhyoung Kim, Suwon-si (KR); Youngseok Byeon, Suwon-si (KR); Dongha Shin, Suwon-si (KR); Myunghun Lee, Suwon-si (KR); Hanmin Nam, Suwon-si (KR); Changhyun Rho, Suwon-si (KR); Jongryul Kim, Suwon-si (KR); Jeunghwan Park, Suwon-si (KR)

(73) Assignee: SAMSUNG ELECTRONICS CO., LTD., Suwon-si (KR)

(21) Appl. No.: 19/547,173

(22) Filed: Feb. 23, 2026

(30) Foreign Application Priority Data
Apr. 17, 2025 (KR) 10-2025-0050422

(51) Int. Cl. H10B 80/00; G11C 16/24; H10W 90/00; H10W 90/26

(52) U.S. Cl. CPC H10B 80/00; G11C 16/24; H10W 90/26; H10W 90/792

(57) ABSTRACT

A memory device includes first and second sub-planes, first and second page buffers, a data input/output circuit, and first and second page buffer drivers. The first sub-plane includes memory cells connected to first bit lines. The second sub-plane includes memory cells connected to second bit lines. The first page buffer driver provides data from the first page buffers to the data input/output circuit. The second page buffer driver provides data from the second page buffers to the data input/output circuit. A subset of the first bit lines is connected to a subset of the first page buffers, the remaining first bit lines are connected to a subset of the second page buffers, a subset of the second bit lines is connected to the remaining first page buffers, and the remaining second bit lines are connected to the remaining second page buffers.

### CROSS-REFERENCE TO RELATED APPLICATION

This application is based on and claims priority under 35 U.S.C. §119 to Korean Patent Application No. 10-2025-0050422, filed on Apr. 17, 2025, in the Korean Intellectual Property Office, the disclosure of which is incorporated by reference herein in its entirety.

### BACKGROUND

The present disclosure relates to a nonvolatile memory device, and more particularly, to a nonvolatile memory device including a plurality of sub-planes.

In response to the demand for high-capacity and small nonvolatile memory devices, three-dimensional nonvolatile memory devices have been developed in which a memory cell array and a peripheral circuit are arranged in a vertical direction. As the amount of computation in electronic devices including embedded nonvolatile memory devices increases, there is increasing demand to reduce the power consumption of nonvolatile memory devices. In addition, as the computation speed of electronic devices increases, there is increasing demand to enhance the data input/output speed of nonvolatile memory devices.

### SUMMARY

One or more embodiments provide a memory device capable of maintaining input/output performance regardless of the size of read data.

Further, one or more embodiments provide a memory device capable of performing a low-power read operation based on the size of read data.

In one or more embodiments of the disclosure, a memory device may include: a first sub-plane including a plurality of memory cells connected to a plurality of first bit lines; a second sub-plane including a plurality of memory cells connected to a plurality of second bit lines; first page buffers and second page buffers each configured to sense data from memory cells through a corresponding bit line; a data input/output circuit configured to transmit data through a plurality of data pins; a first page buffer driver configured to provide data from the first page buffers to the data input/output circuit; and a second page buffer driver configured to provide data from the second page buffers to the data input/output circuit, wherein a first subset of the plurality of first bit lines may be connected to a first subset of the first page buffers, a second subset of the plurality of first bit lines may be connected to a first subset of the second page buffers, a first subset of the plurality of second bit lines may be connected to a second subset of the first page buffers, and a second subset of the plurality of second bit lines may be connected to a second subset of the second page buffers.

In one or more embodiments of the disclosure, a memory device may include: a first sub-plane including a plurality of memory cells; a second sub-plane including a plurality of memory cells; a first bit line group including a plurality of first bit lines that may be connected to the first sub-plane, extend in a first horizontal direction, and may be arranged in a second horizontal direction perpendicular to the first horizontal direction; a second bit line group including a plurality of second bit lines that may be connected to the second sub-plane, extend in the first horizontal direction, and may be arranged in the second horizontal direction, the second bit line group being apart from the first bit line group in the first horizontal direction by a bit line cut region; a first extension line group including a plurality of first extension lines that may be connected to a first subset of the plurality of second bit lines and extend across the bit line cut region from a region vertically overlapping the first subset of the plurality of second bit lines to a region vertically overlapping a first subset of the plurality of first bit lines; a second extension line group including a plurality of second extension lines that may be connected to a second subset of the plurality of first bit lines and extend across the bit line cut region from a region vertically overlapping the second subset of the plurality of first bit lines to a region vertically overlapping a second subset of the plurality of second bit lines; and a page buffer circuit including page buffers connected to the first bit line group and the second bit line group through the first extension line group and the second extension line group.

In one or more embodiments of the disclosure, a memory device may include: a plurality of sub-planes connected to a plurality of bit line groups including a first bit line group and a second bit line group, each of the first bit line group and the second bit line group including a plurality of bit lines; a plurality of page buffer groups including a first page buffer group and a second page buffer group, each of the first page buffer group and the second page buffer group including a plurality of page buffers each configured to sense data through a corresponding bit line; a data input/output circuit configured to transmit data through a plurality of data pins; and a plurality of page buffer drivers each configured to provide data sensed by a page buffer group to the data input/output circuit, wherein a first number of first bit lines included in the first bit line group may be connected to a first number of first page buffers included in the first page buffer group, a second number of first bit lines included in the first bit line group may be connected to a second number of second page buffers included in the second page buffer group, a third number of second bit lines included in the second bit line group may be connected to a third number of first page buffers included in the first page buffer group, and a fourth number of second bit lines included in the second bit line group may be connected to a fourth number of second page buffers included in the second page buffer group.

According to an aspect of the inventive concept, there is provided a memory device including a first sub-plane, a second sub-plane, first page buffers, second page buffers, a data input/output circuit, a first page buffer driver, and a second page buffer driver. The first sub-plane includes a plurality of memory cells connected to a plurality of first bit lines. The second sub-plane includes a plurality of memory cells connected to a plurality of second bit lines. The first and second page buffers are each configured to sense data from memory cells through a corresponding bit line. The data input/output circuit is configured to transmit data through a plurality of data pins. The first page buffer driver is configured to provide data from the first page buffers to the data input/output circuit. The second page buffer driver is configured to provide data from the second page buffers to the data input/output circuit. A subset of the plurality of first bit lines is connected to a subset of the first page buffers, a remainder of the plurality of first bit lines are connected to a subset of the second page buffers, a subset of the plurality of second bit lines is connected to a remainder of the first page buffers, and a remainder of the plurality of second bit lines are connected to a remainder of the second page buffers.

According to another aspect of the inventive concept, there is provided a memory device including a first sub-plane, a second sub-plane, a first bit line group, a second bit line group, a first extension line group, a second extension line group, and a page buffer circuit. The first sub-plane includes a plurality of memory cells. The second sub-plane includes a plurality of memory cells. The first bit line group includes a plurality of first bit lines that are connected to the first sub-plane, extend in a first horizontal direction, and are arranged in a second horizontal direction perpendicular to the first horizontal direction. The second bit line group includes a plurality of second bit lines that are connected to the second sub-plane, extend in the first horizontal direction, and are arranged in the second horizontal direction, the second bit line group being apart from the first bit line group in the first horizontal direction by a bit line cut region. The first extension line group includes a plurality of first extension lines that are connected to a subset of the plurality of second bit lines and extend across the bit line cut region from a region vertically overlapping the subset of the plurality of second bit lines to a region vertically overlapping a subset of the plurality of first bit lines. The second extension line group includes a plurality of second extension lines that are connected to a remainder of the plurality of first bit lines and extend across the bit line cut region from a region vertically overlapping the remainder of the plurality of first bit lines to a region vertically overlapping a remainder of the plurality of second bit lines. The page buffer circuit includes page buffers connected to the first bit line group and the second bit line group through the first extension line group and the second extension line group.

According to another aspect of the inventive concept, there is provided a memory device including a plurality of sub-planes, a plurality of page buffer groups, a data input/output circuit, a plurality of page buffer drivers. The plurality of sub-planes are connected to a plurality of bit line groups each including a plurality of bit lines. The plurality of page buffer groups each including a plurality of page buffers each configured to sense data through a corresponding bit line. The data input/output circuit is configured to transmit data through a plurality of data pins. The plurality of page buffer drivers are each configured to provide data sensed by a page buffer group to the data input/output circuit. A first number of first bit lines included in a first bit line group of the plurality of bit line groups is connected to a first number of first page buffers included in a first page buffer group of the plurality of page buffer groups, a second number of first bit lines included in in the first bit line group is connected to a second number of second page buffers included in a second page buffer group of the plurality of page buffer groups, a third number of second bit lines included in a second bit line group of the plurality of bit line groups is connected to a third number of first page buffers included in the first page buffer group, and a fourth number of second bit lines included in the second bit line group is connected to a fourth number of second page buffers included in the second page buffer group.

In addition, the third number of second bit lines is connected to a second line that extends in a second wiring layer from a region vertically overlapping the second page buffers to a region vertically overlapping the third number of first page buffers.

### BRIEF DESCRIPTION OF DRAWINGS

Embodiments will be more clearly understood from the following detailed description taken in conjunction with the accompanying drawings in which:

FIG. 1 is an example block diagram illustrating a memory device according to an embodiment;

FIG. 2 is an example block diagram illustrating a memory device according to a comparative example;

FIG. 3 is a circuit diagram illustrating a memory block according to an embodiment;

FIG. 4 is a view schematically illustrating a structure of a memory device according to an embodiment;

FIG. 5 is a view schematically illustrating a structure of a memory device according to an embodiment;

FIG. 6 is a view schematically illustrating a structure of a memory device according to an embodiment;

FIG. 7 is an example view illustrating connection between a first sub-plane and a page buffer circuit, according to an embodiment;

FIG. 8 a view illustrating a page buffer according to an embodiment;

FIG. 9 is a circuit diagram illustrating a cache unit according to an embodiment;

FIG. 10 is a block diagram illustrating a page buffer circuit and a data input/output circuit, according to an embodiment;

FIG. 11 is a plan view illustrating a memory device according to an embodiment;

FIGS. 12A-12D are cross-sectional views illustrating a memory device according to embodiments;

FIGS. 13A-13D are cross-sectional views illustrating a memory device according to embodiments;

FIGS. 14A and 14B are layouts illustrating an arrangement of bit lines and extension lines, according to embodiments;

FIGS. 15A-15C are layouts illustrating an arrangement of bit lines and extension lines, according to embodiments;

FIGS. 16A and 16B are layouts illustrating an arrangement of bit lines and extension lines, according to embodiments;

FIG. 17 is a plan view illustrating a memory device according to an embodiment;

FIGS. 18A and 18B are cross-sectional views illustrating a memory device according to embodiments;

FIG. 19 is a view illustrating a memory device according to an embodiment; and

FIG. 20 is a view illustrating a solid-state drive (SSD) including memory devices according to an embodiment.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail

In the present specification, an X-axis direction may be referred to as a first horizontal direction, a Y-axis direction may be referred to as a second horizontal direction, and a Z-axis direction may be referred to as a vertical direction. However, the inventive concept is not limited thereto. The Y-axis direction may also be referred to as a first horizontal direction, and the X-axis direction may also be referred to as a second horizontal direction.

The term “an embodiment” is intended to encompass one or more embodiments, rather than being limited to a single example. Furthermore, features described in embodiments may be combined and implemented together.

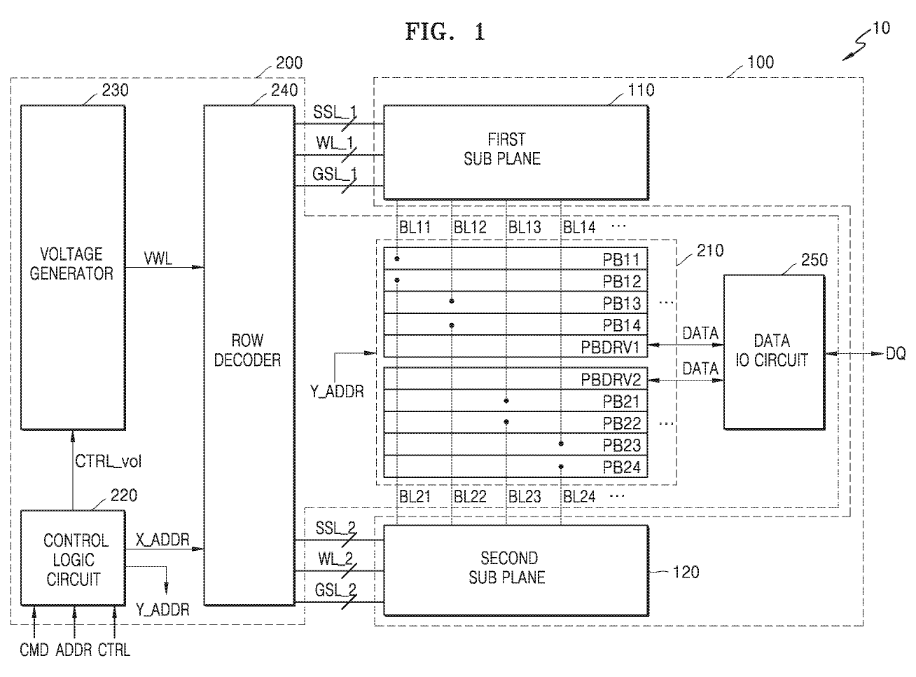

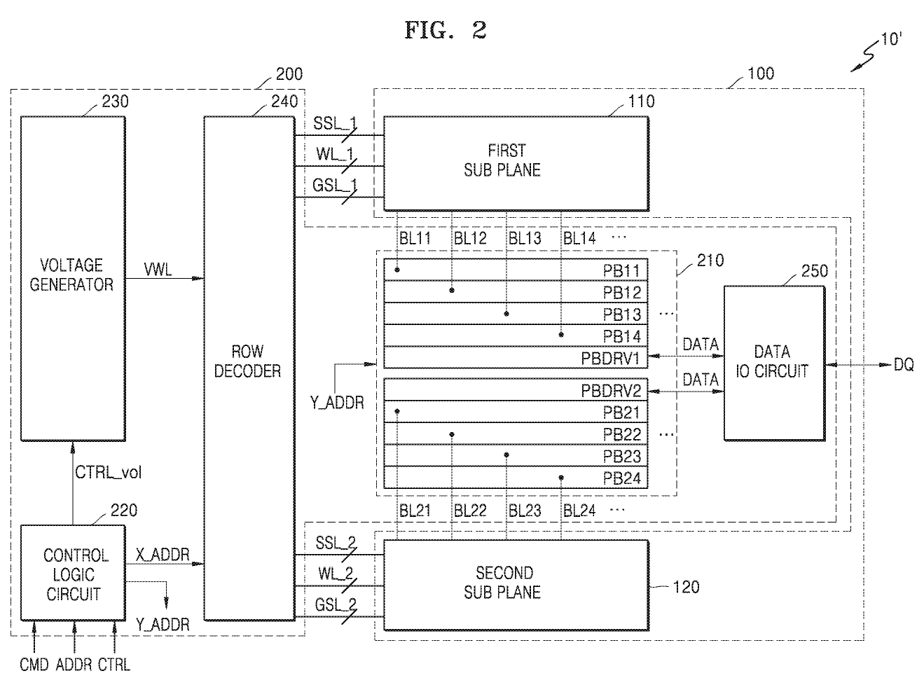

FIG. 1 is an example block diagram illustrating a memory device 10 according to an embodiment. FIG. 2 is an example block diagram illustrating a memory device 10′ according to a comparative example.

Referring to FIG. 1, the memory device 10 may include a memory cell array 100 and a peripheral circuit 200. The peripheral circuit 200 may include a page buffer circuit 210, a control logic circuit 220, a voltage generator 230, a row decoder 240, and a data input/output circuit 250. The memory device 10 may further include a column decoder, a pre-decoder, a temperature sensor, a command decoder, and an address decoder. The memory device 10 may refer to a “nonvolatile memory device.”

The memory cell array 100 may include a plurality of sub-planes including a first sub-plane 110 and a second sub-plane 120. According to an embodiment, the memory cell array 100 may include at least one plane or memory plane, and each plane may include a plurality of sub-planes. In the present specification, the memory cell array 100 is described as including two sub-planes, but the inventive concept is not limited thereto. For example, the memory cell array 100 may include three or more sub-planes. A plane may refer to a larger logical or physical division within the memory cell array, and may, for instance, support 16 KB page read operations. A sub-plane may represent a smaller partition of the plane, each capable of independently supporting a smaller page size, for example, 8 KB per sub-plane. Thus, a single 16 KB page in a plane may be composed of two 8 KB pages from two sub-planes. However, the inventive concept is not limited thereto.

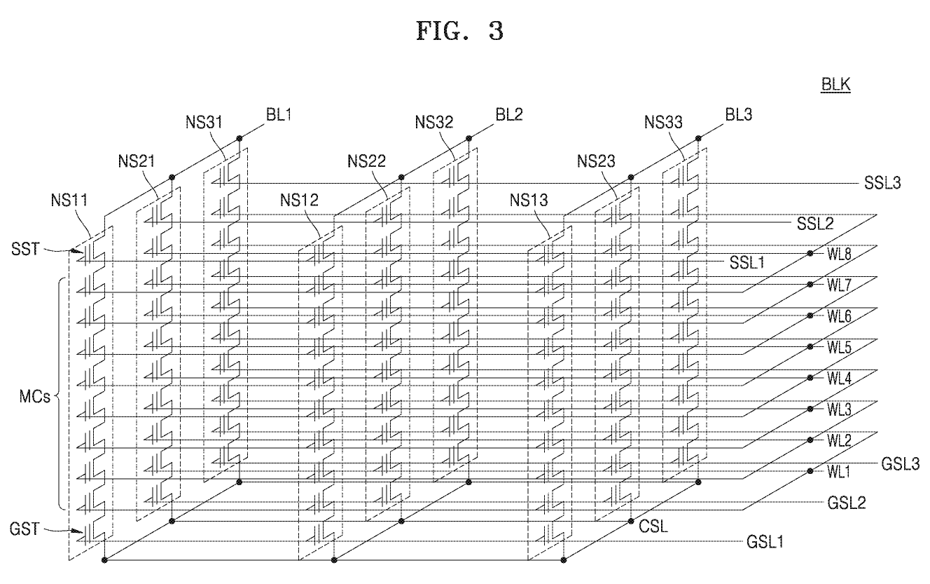

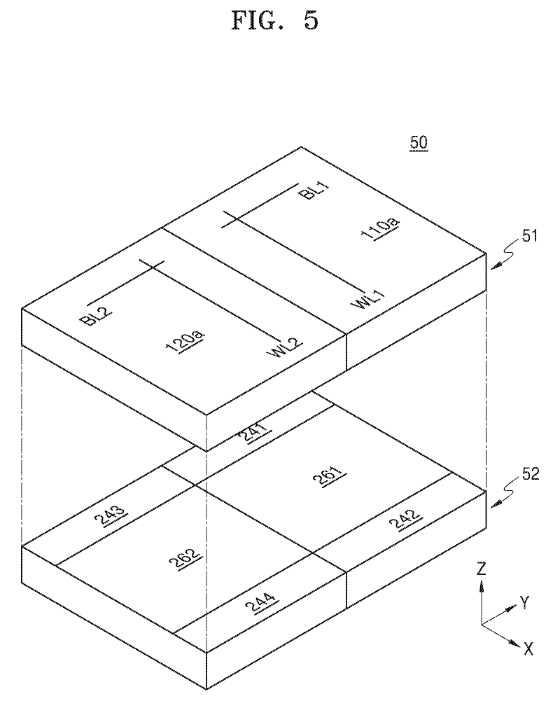

The first sub-plane 110 and the second sub-plane 120 may be adjacent to each other in a first horizontal direction (e.g., a Y-axis direction in FIG. 5). The first sub-plane 110 and the second sub-plane 120 may each include a plurality of memory blocks, and each of the memory blocks may include a plurality of memory cells. This is described below with reference to FIG. 3. The first sub-plane 110 may be connected to the page buffer circuit 210 through bit lines BL11, BL12, BL13, and BL14, and may be connected to the row decoder 240 through a string select line SSL_1, a word line WL_1, and a ground select line GSL_1. The bit lines BL11, BL12, BL13, and BL14 connected to the first sub-plane 110 may be referred to as a first bit line group. The second sub-plane 120 may be connected to the page buffer circuit 210 through bit lines BL21, BL22, BL23, and BL24, and may be connected to the row decoder 240 through a string select line SSL_2, a word line WL_2, and a ground select line GSL_2. The bit lines BL21, BL22, BL23, and BL24 connected to the second sub-plane 120 may be referred to as a second bit line group. The first sub-plane 110 and the second sub-plane 120 may be controlled independently of each other. For example, a program operation, a read operation, and an erase operation on the first sub-plane 110 may be controlled independently of a program operation, a read operation, and an erase operation on the second sub-plane 120. The memory cells included in the memory cell array 100 may be flash memory cells. Hereinafter, embodiments will be described by taking as an example a case in which the memory cells are NAND flash memory cells. However, the inventive concept is not limited thereto, and in some embodiments, the memory cells may be resistive memory cells such as resistive random access memory (ReRAM) cells, phase change RAM (PRAM) cells, or magnetic RAM (MRAM) cells.

In an embodiment, the memory cell array 100 may include a three-dimensional memory cell array, and the three-dimensional memory cell array may include a plurality of NAND strings. Each of the NAND strings may include memory cells respectively connected to word lines stacked vertically on a substrate. This is described below with reference to FIG. 3.

The page buffer circuit 210 may include a plurality of page buffers PB11 to PB14 and PB21 to PB24, and the page buffers PB11 to PB14 and PB21 to PB24 may each be connected to memory cells through the bit lines BL11 to BL14 and BL21 to BL24. The page buffers PB11 to PB14 may be referred to as a first page buffer group, and the page buffers PB21 to PB24 may be referred to as a second page buffer group. Although the page buffer circuit 210 is illustrated as including eight page buffers with four page buffers included in the first page buffer group and four page buffers included in the second page buffer group, the inventive concept is not limited thereto.

The page buffer circuit 210 may select at least one bit line among the bit lines BL11 to BL14 and BL21 to BL24 in response to a column address Y-ADDR. The page buffer circuit 210 may operate as a write driver or a sense amplifier depending on operation modes. For example, during a program operation, the page buffer circuit 210 may apply a bit line voltage corresponding to data to be programmed to a selected bit line. During a read operation, the page buffer circuit 210 may detect current or voltage of a selected bit line to sense data stored in memory cells.

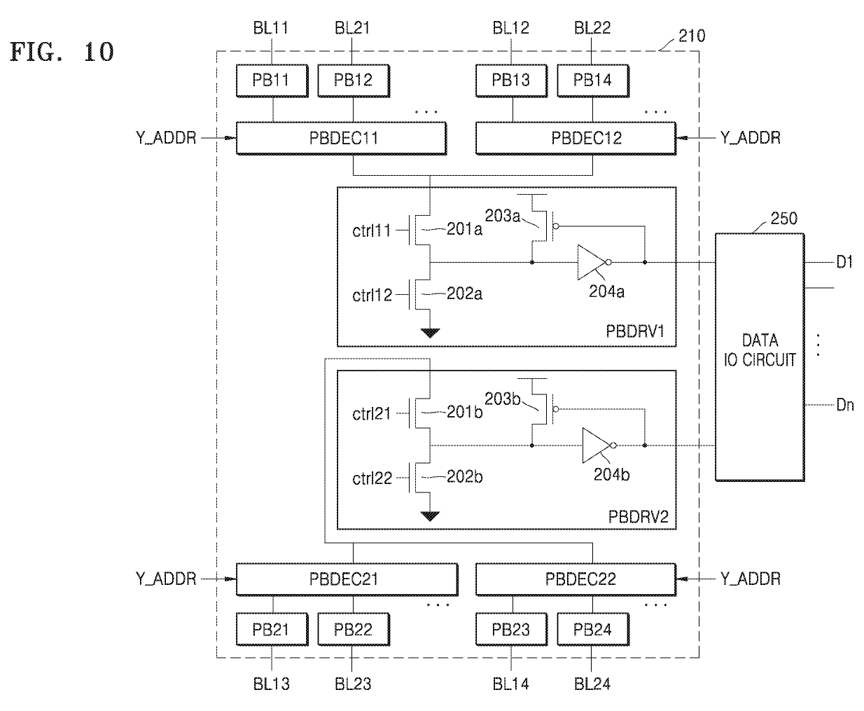

The page buffer circuit 210 may include page buffer drivers PBDRV1 and PBDRV2. The page buffer drivers PBDRV1 and PBDRV2 may operate as sense amplifiers during a read operation or a verify operation. In addition, the page buffer drivers PBDRV1 and PBDRV2 may operate as write drivers during a program operation. Example structures of the page buffer drivers PBDRV1 and PBDRV2 are described below with reference to FIG. 10, but the structures of the page buffer drivers PBDRV1 and PBDRV2 are not limited thereto. The page buffer driver PBDRV1 may provide data DATA received from the data input/output circuit 250 to the first page buffer group, or provide data DATA received from the first page buffer group to the data input/output circuit 250. The page buffer driver PBDRV2 may provide data DATA received from the data input/output circuit 250 to the second page buffer group, or provide data DATA received from the second page buffer group to the data input/output circuit 250. Although two page buffer drivers are illustrated, the inventive concept is not limited thereto.

The control logic circuit 220 may globally control various operations within the memory device 10. The control logic circuit 220 may output various control signals, such as a row address X_ADDR, a column address Y_ADDR, and a voltage control signal CTRL_vol, based on a command CMD, an address ADDR, and a control signal CTRL, to program data to the memory cell array 100, read data from the memory cell array 100, or erase data stored in the memory cell array 100. The row address X_ADDR may be provided to the row decoder 240, the column address Y_ADDR may be provided to the page buffer circuit 210, and the voltage control signal CTRL_vol may be provided to the voltage generator 230.

The voltage generator 230 may generate various types of voltages for performing program, read, and erase operations based on the voltage control signal CTRL_vol. For example, the voltage generator 230 may generate a program voltage, a read voltage, a program verify voltage, or an erase voltage as a word line voltage VWL. The voltage generator 230 may provide the word line voltage VWL to the row decoder 240.

The row decoder 240 may select at least one of the memory blocks included in the first sub-plane 110 and the second sub-plane 120 in response to the row address X-ADDR. The row decoder 240 may select one of a plurality of word lines WL in the selected at least one memory block and may select at least one of a plurality of string select lines

SSL_1 and SSL_2. For example, during a program operation, the row decoder 240 may apply a program voltage and a program verify voltage to the selected word line, and during a read operation, the row decoder 240 may apply a read voltage to the selected word line.

The data input/output circuit 250 may receive data DATA from the page buffer drivers PBDRV1 and PBDRV2 or may provide data DATA to the page buffer drivers PBDRV1 and PBDRV2. The data input/output circuit 250 may transmit data to an external device (for example, a memory controller) or receive data from an external device through DQ pins.

Referring to FIG. 1, some (or a subset) of bit lines, such as the bit lines BL11 and BL12, included in the first bit line group may be connected to some (or a subset) of page buffers, such as the page buffers PB11 and PB13, included in the first page buffer group, and the remaining bit lines, such as the bit lines BL13 and BL14, included in the first bit line group may be connected to some (or a subset) of page buffers, such as the page buffers PB21 and PB23, included in the second page buffer group. That is, a first number of bit lines, such as the bit lines BL11 and BL12, included in the first bit line group may be connected to a first number of page buffers, such as the page buffers PB11 and PB13, included in the first page buffer group, and a second number of bit lines, such as the bit lines BL13 and BL14, included in the first bit line group may be connected to a second number of page buffers, such as the page buffers PB21 and PB23, included in the second page buffer group.

Some (or a subset) of bit lines, such as the bit lines BL21 and BL22, included in the second bit line group may be connected to the remaining page buffers, such as the page buffers PB12 and PB14, included in the first page buffer group, and the remaining bit lines, such as the bit lines BL23 and BL24, included in the second bit line group may be connected to the remaining page buffers, such as the page buffers PB22 and PB24, included in the second page buffer group. That is, a third number of bit lines, such as the bit lines BL21 and BL22, included in the second bit line group may be connected to a third number of page buffers, such as the page buffers PB12 and PB14, included in the first page buffer group, and a fourth number of bit lines, such as the bit lines BL23 and BL24, included in the second bit line group may be connected to a fourth number of page buffers, such as the page buffers PB22 and PB24, included in the second page buffer group.

In some embodiments, during a 16-KB read operation, both the first sub-plane 110 and the second sub-plane 120 may be sensed. For example, some page buffers, such as the page buffers PB11 and PB13, included in the first page buffer group, and some page buffers, such as the page buffers PB21 and PB23, included in the second page buffer group may sense 8 KB of data from the first sub-plane 110 through the bit lines BL11 to BL14 of the first bit line group. In addition, the remaining page buffers, such as the page buffers PB12 and PB14, included in the first page buffer group, and the remaining page buffers, such as the page buffers PB22 and PB24, included in the second page buffer group may sense 8 KB of data from the second sub-plane 120 through the bit lines BL21 to BL24 of the second bit line group. The page buffer driver PBDRV1 may receive data sensed by the page buffers PB11 to PB14 of the first page buffer group and may provide the received data to the data input/output circuit 250. For example, the page buffer driver PBDRV1 may receive 4 KB of data from the first sub-plane 110 via some page buffers such as the page buffers PB11 and PB13, and 4 KB of data from the second sub-plane 120 via the remaining page buffers such as the page buffers PB12 and PB14. The page buffer driver PBDRV2 may receive data sensed by the page buffers PB21 to PB24 of the second page buffer group and may provide the received data to the data input/output circuit 250. For example, the page buffer driver PBDRV2 may receive 4 KB of data from the first sub-plane 110 via some page buffers such as the page buffers PB21 and PB23, and 4 KB of data from the second sub-plane 120 via the remaining page buffers such as the page buffers PB22 and PB24. That is, during a 16-KB read operation, both the page buffer drivers PBDRV1 and PBDRV2 may be used.

In some embodiments, during an 8-KB read operation, only one of the first sub-plane 110 and the second sub-plane 120 may be sensed. For example, only the first sub-plane 110 may be sensed. For example, some page buffers, such as the page buffers PB11 and PB13, included in the first page buffer group, and some page buffers, such as the page buffers PB21 and PB23, included in the second page buffer group may sense 8 KB of data from the first sub-plane 110 through the bit lines BL11 to BL14 of the first bit line group. The page buffer driver PBDRV1 may receive the data sensed by some page buffers, such as the page buffers PB11 and PB13, included in the first page buffer group and may provide the received data to the data input/output circuit 250. For example, the page buffer driver PBDRV1 may receive 4 KB of data of the first sub-plane 110 from some page buffers such as the page buffers PB11 and PB13. The page buffer driver PBDRV2 may receive the data sensed by some page buffers, such as the page buffers PB21 and PB23, included in the second page buffer group and may provide the received data to the data input/output circuit 250. For example, the page buffer driver PBDRV2 may receive 4 KB of data of the first sub- plane 110 from some page buffers, such as the page buffers PB21 and PB23. That is, during an 8-KB read operation, both the page buffer drivers PBDRV1 and PBDRV2 may be used.

In some embodiments, during a 4-KB read operation, only one of the first sub-plane 110 and the second sub-plane 120 may be sensed. For example, only the first sub-plane 110 may be sensed. For example, the page buffer PB11 of the first page buffer group and the page buffer PB21 of the second page buffer group may sense 4KB of data from the first sub-plane 110 through the bit lines BL11 and BL13 of the first bit line group. The page buffer driver PBDRV1 may receive the data sensed by the page buffer PB11 of the first page buffer group and may provide the received data to the data input/output circuit 250. For example, the page buffer driver PBDRV1 may receive 2 KB of data of the first sub-plane 110 from the page buffer PB11. The page buffer driver PBDRV2 may receive the data sensed by the page buffer PB21 of the second page buffer group and may provide the received data to the data input/output circuit 250. For example, the page buffer driver PBDRV2 may receive 2 KB of data of the first sub-plane 110 from the page buffer PB21. That is, during a 4-KB read operation, both the page buffer drivers PBDRV1 and PBDRV2 may be used.

According to an embodiment, because both the page buffer drivers PBDRV1 and PBDRV2 are used regardless of the size of read data, the input/output (IO) performance of the page buffer circuit 210 when transmitting data to the data input/output circuit 250 may be maintained.

According to an embodiment, during a read operation for low-sized data (e.g., 8 KB, 4KB, etc.), only one of the first sub-plane 110 and the second sub-plane 120 may be read. Therefore, only word lines of a sub-plane to be read may be driven, and thus, power consumption may be reduced during read operations.

Referring to FIG. 2, in the memory device 10′ according to the comparative example, a first bit line group is connected to a first page buffer group, and a second bit line group is connected to a second page buffer group. For example, bit lines BL11 to BL14 are respectively connected to page buffers PB11 to PB14, and bit lines BL21 to BL24 are respectively connected to page buffers PB21 to PB24. During a 16-KB read operation on the first sub-plane 110 and the second sub-plane 120, the first page buffer group may sense 8KB of data from the first sub-plane 110, and the second page buffer group may sense 8KB of data from the second sub-plane 120. A page buffer driver PBDRV1 may receive the 8KB of data from the first page buffer group and provide the 8KB of data to the data input/output circuit 250. A page buffer driver PBDRV2 may receive the 8KB of data from the second page buffer group and provide the 8KB of data to the data input/output circuit 250. That is, during a 16-KB read operation, both the page buffer drivers PBDRV1 and PBDRV2 may be used. However, during an 8-KB read operation on the first sub-plane 110, only the first page buffer group performs sensing, and 8KB of data is provided to the data input/output circuit 250 through the page buffer driver PBDRV1. Therefore, IO performance may be lower in 8-KB read operations than in 16-KB read operations.

FIG. 3 is a circuit diagram illustrating a memory block BLK according to an embodiment.

Referring to FIG. 3, the memory block BLK may correspond to one of the memory blocks included in the first sub-plane 110 and the second sub-plane 120 shown in FIG. 1. The memory block BLK includes NAND strings NS11 to NS33, and each of the NAND strings NS11 to NS33 (e.g., the NAND string NS11) may include a string select transistor SST, a plurality of memory cells MCs connected in series to each other, and a ground select transistor GST. The string select transistor, the memory cells MCs, and the ground select transistor GST, included in each of the NAND strings NS11 to NS33, may form a structure stacked in a vertical direction on a substrate.

First to third bit lines BL1 to BL3 may extend in a first horizontal direction (e.g., a Y-axis direction in FIG. 5), and word lines WL1 to WL8 may extend in a second horizontal direction (e.g., an X direction in FIG. 5). The NAND strings NS11, NS21, and NS31 may be provided between the first bit line BL1 and a common source line CSL. The NAND strings NS12, NS22, and NS32 may be provided between the second bit line BL2 and the common source line CSL. The NAND strings NS13, NS23, and NS33 may be provided between the third bit line BL3 and the common source line CSL. For example, the first to third bit lines BL1 to BL3 may correspond to the bit lines BL11 to BL14 shown in FIG. 1 or may correspond to the bit lines BL21 to BL24 shown in FIG. 1.

The string select transistors SST may be connected to corresponding string select lines SSL1 to SSL3. The memory cells MCs may each be connected to a corresponding word line among the word lines WL1 to WL8. The ground select transistors GST may be connected to corresponding ground select lines GSL1 to GSL3. The string select transistors SST may be connected to corresponding bit lines, and the ground select transistors GST may be connected to the common source line CSL. Here, the number of NAND strings, the number of word lines, the number of bit lines, the number of ground select lines, and the number of string select lines may vary depending on embodiments.

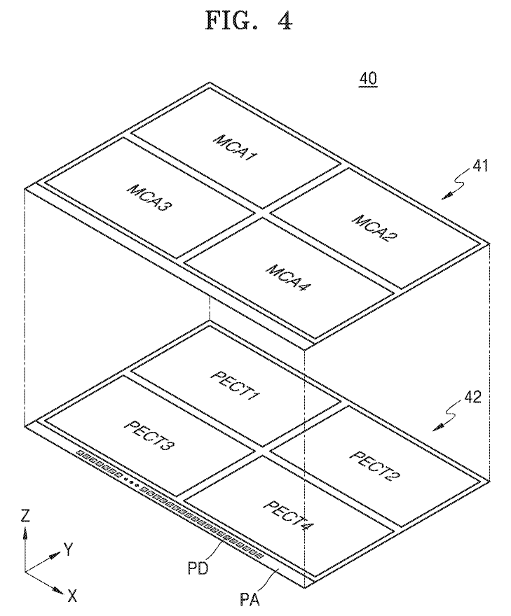

FIG. 4 is a view schematically illustrating a structure of a memory device 40 according to an embodiment.

Referring to FIG. 4, the memory device 40 may include a memory cell region 41 and a peripheral circuit region 42, and may correspond to an implementation example of the memory device 10 shown in FIG. 1. The memory cell region 41 may be formed on a first wafer and may thus be referred to as a memory chip or a first semiconductor chip. The peripheral circuit region 42 may be formed on a second wafer and may thus be referred to as a peripheral circuit chip or a second semiconductor chip. In an embodiment, the memory cell region 41 and the peripheral circuit region 42 may be connected in a vertical direction (e.g., a Z-axis direction) by a bonding method. Therefore, the memory device 40 may be referred to as a bonding vertical NAND (B-VNAND) memory device, or a memory device having a chip-to-chp (C2C) bonding structure.

In an embodiment, the memory cell region 41 may include first to fourth memory cell arrays MCA1 to MCA4. For example, one of the first to fourth memory cell arrays MCA1 to MCA4 may correspond to the memory cell array 100 shown in FIG. 1. In this case, each of the first to fourth memory cell arrays MCA1 to MCA4 may be referred to as a memory plane or a memory array tile (MAT), and thus, the memory cell region 41 may have a 4-MAT structure. The peripheral circuit region 42 may include first to fourth peripheral circuits PECT1 to PECT4 respectively corresponding to the first to fourth memory cell arrays MCA1 to MCA4. For example, one of the first to fourth peripheral circuits PECT1 to PECT4 may correspond to the peripheral circuit 200 shown in FIG. 1. In addition, the peripheral circuit region 42 may further include an external pad bonding region PA in which a plurality of pads PD are arranged.

Each of the first to fourth memory cell arrays MCA1 to MCA4 may include a plurality of sub-planes arranged in a first horizontal direction (X-axis direction) and/or a second horizontal direction (Y-axis direction).

FIG. 5 is a view schematically illustrating a structure of a memory device 50 according to an embodiment.

Referring to FIG. 5, the memory device 50 may include a memory cell region 51 and a peripheral circuit region 52, and may correspond to an implementation example of the memory device 10 shown in FIG. 1. For example, the memory cell array 100 shown in FIG. 1 may be provided in the memory cell region 51, and the peripheral circuit 200 shown in FIG. 1 may be provided in the peripheral circuit region 52.

The memory cell region 51 may include a first sub-plane region 110a and a second sub-plane region 120a. A first sub-plane may be provided in a first sub-plane region 110a, and a second sub-plane may be provided in a second sub-plane region 120a. The first sub-plane may be connected to a bit line BL1 and a word line WL1, and the second sub-plane may be connected to a bit line BL2 and a word line WL2. Each of the bit lines BL1 and BL2 may extend in a second horizontal direction. The bit lines BL1 and BL2 may be arranged apart from each other in the second horizontal direction. Each of the word lines WL1 and WL2 may extend in a first horizontal direction. The memory device 50 is described as including one memory cell array that includes two sub-planes, but the number of memory cell arrays and the number of sub-planes included in the memory device 50 are not limited thereto.

The peripheral circuit region 52 may include row decoder regions 241, 242, 243, and 244 and circuit regions 261 and 262. The row decoder 240 shown in FIG. 1 may be distributed in the row decoder regions 241 and 244. For example, row decoder portions connected to the first sub-plane may be arranged in row decoder regions 241 and 242, and row decoder portions connected to the second sub-plane may be arranged in row decoder regions 243 and 244. The row decoder regions 241 and 242 may vertically overlap the first sub-plane region 110a, and the row decoder regions 243 and 244 may vertically overlap the second sub-plane region 120a. Although two row decoder regions are shown as being arranged for each sub-plane, the inventive concept is not limited thereto.

Components of the peripheral circuit 200 shown in FIG. 1, excluding the row decoder 240, may be arranged in the circuit regions 261 and 262. For example, the page buffers PB11 to PB14 included in the first page buffer group and the page buffer driver PBDRV1 shown in FIG. 1 may be arranged in the circuit region 261, and the page buffers PB21 to PB24 included in the second page buffer group and the page buffer driver PBDRV2 shown in FIG. 1 may be arranged in the circuit region 262. The circuit region 261 may vertically overlap the first sub-plane region 110a, and the circuit region 262 may vertically overlap the second sub-plane region 120a.

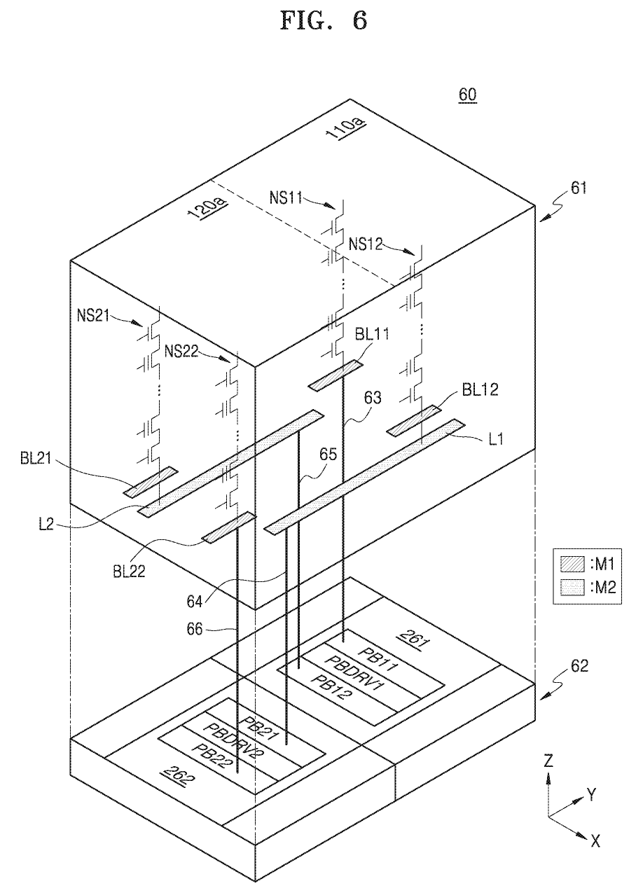

FIG. 6 is a view schematically illustrating a structure of a memory device 60 according to an embodiment.

Referring to FIG. 6, the memory device 60 may include a memory cell region 61 and a peripheral circuit region 62, and may correspond to an implementation example of the memory device 10 shown in FIG. 1.

Referring to FIG. 6, NAND strings NS11 and NS12 may be arranged in a first sub-plane region 110a, and NAND strings NS21 and NS22 may be arranged in a second sub-plane region 120a. The NAND string NS11 may be connected to a bit line BL11, the NAND string NS12 may be connected to a bit line BL12, the NAND string NS21 may be connected to a bit line BL21, and the NAND string NS22 may be connected to a bit line BL22. The bit lines BL11 and BL12 of FIG. 6 may correspond to the bit lines BL11 and BL13 of FIG. 1, and the bit lines BL21 and BL22 of FIG. 6 may correspond to the bit lines BL21 and BL23 of FIG. 1, but embodiments are not limited thereto.

Page buffers PB11 and PB12 of a first page buffer group and a first page buffer driver PBDRV1 may be arranged in a circuit region 261, and page buffers PB21 and PB22 of a second page buffer group and a second page buffer driver PBDRV2 may be arranged in a circuit region 262.

The bit lines BL11, BL12, BL21, BL22 may be formed in a first wiring layer M1. The bit lines BL11 and BL12 included in the first bit line group may extend in a second horizontal direction and may be apart from each other in a first horizontal direction. The bit lines BL21 and BL22 included in the second bit line group may extend in the second horizontal direction and may be apart from each other in the first horizontal direction. The first bit line group and the second bit line group may be arranged apart from each other in the second horizontal direction.

The bit line BL11 may be connected to the page buffer PB11 provided in the circuit region 261. For example, the bit line BL11 may be connected to the page buffer PB11 through a vertically extending structure 63. The bit line BL12 may be connected to the page buffer PB21 provided in the circuit region 262. For example, the bit line BL12 may be connected to the page buffer PB21 through a first extension line L1, which extends in a second wiring layer M2 in the second horizontal direction, and a vertically extending structure 64. The first extension line L1 may extend to a position overlapping the second sub-plane region 120a. The bit line BL21 may be connected to the page buffer PB12 provided in the circuit region 261. For example, the bit line BL21 may be connected to the page buffer PB12 through a second extension line L2, which extends in the second wiring layer M2 in the second horizontal direction, and a vertically extending structure 65. The second extension line L2 may extend to a position overlapping the first sub-plane region 110a. The bit line BL22 may be connected to the page buffer PB22 provided in the circuit region 262. For example, the bit line BL22 may be connected to the page buffer PB22 through a vertically extending structure 66.

The memory cell region 61 may be flipped and then attached to the peripheral circuit region 62. That is, when the memory cell region 61 is fabricated in a non-flipped state, the first wiring layer M1 may be formed below the second wiring layer M2, and after the fabrication of the memory cell region 61 is completed, the memory cell region 61 may be flipped and attached to the peripheral circuit region 62. That is, although FIG. 6 illustrates that the first wiring layer M1 is in an +Z-axis direction relative to the second wiring layer M2, the second wiring layer M2 may be formed above the first wiring layer M1 during the formation of the memory cell region 61. Based on a non-flipped state of the memory cell region 61, an upper side may indicate the +Z-axis direction, and a lower side may indicate an -Z-axis direction.

In a read operation, the first page buffer driver PBDRV1 may receive data stored in the NAND strings NS11 and NS21 via the page buffers PB11 and PB12. That is, the first page buffer driver PBDRV1 may receive data stored in two sub-planes. The second page buffer driver PBDRV2 may receive data stored in the NAND strings NS12 and NS22 via the page buffers PB21 and PB22. That is, the second page buffer driver PBDRV2 may receive data stored in two sub-planes.

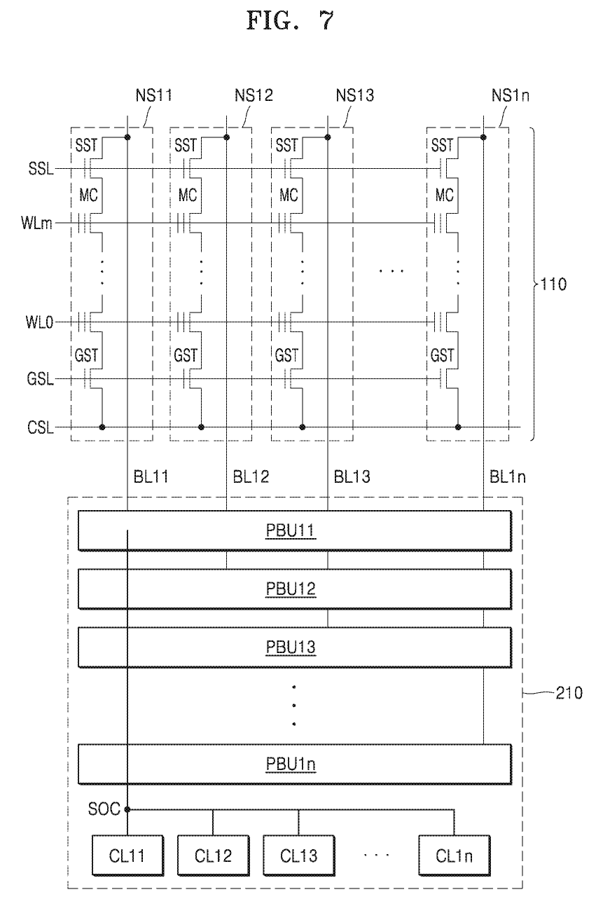

FIG. 7 is an example view illustrating connection between a first sub-plane 110 and a page buffer circuit 210 according to an embodiment.

Referring to FIG. 7, the first sub-plane 110 may include first to nth NAND strings NS11 to NS1n. Each of the first to nth NAND strings NS11 to NS1n may include a ground select transistor GST connected to a ground select line GSL, a plurality of memory cells MC respectively connected to a plurality of word lines WL0 to WLm, and a string select transistor SST connected to a string select line SSL. The ground select transistor GST, the memory cells MC, and the string select transistor SST may be connected in series to each other. Here, m refers to a positive integer. The description of the first sub-plane 110 may also apply to the second sub-plane 120 (see FIG. 1).

The page buffer circuit 210 may include first to nth page buffer units PBU11 to PBU1n. The first page buffer unit PBU11 may be connected to the first NAND string NS11 through a first bit line BL11, and the nth page buffer unit PBU1n may be connected to the nth NAND string NS1n through an nth bit line BL1n. Here, n refers to a positive integer. For example, the first to nth page buffer units PBU11 to PBU1n may be arranged in a line in a second horizontal direction in which first to nth bit lines BL11 to BL1n extend. The first to nth page buffer units PBU11 to PBU1n may be included in a first page buffer group. Therefore, the first to nth page buffer units PBU11 to PBU1n may be arranged in the circuit region 261 (see FIG. 7).

The page buffer circuit 210 may further include first to nth cache latches CL11 to CL1n respectively corresponding to the first to nth page buffer units PBU11 to PBU1n. The first to nth cache latches CL11 to CL1n may be arranged in a line in the extension direction of the first to nth bit lines BL11 to BL1n. The first to nth cache latches CL11 to CL1n may be included in the first page buffer group. Therefore, the first to nth cache latches CL11 to CL1n may be arranged in the circuit region 261 (see FIG. 7) .

Sensing nodes of the first to nth page buffer units PBU11 to PBU1n may be commonly connected to a binding sensing node SOC. In addition, the first to nth cache latches CL11 to CL1n may also be commonly connected to the biding sensing node SOC. Therefore, the first to nth page buffer units PBU11 to PBU1n may be connected to the first to nth cache latches CL11 to CL1n through the binding sensing node SOC.

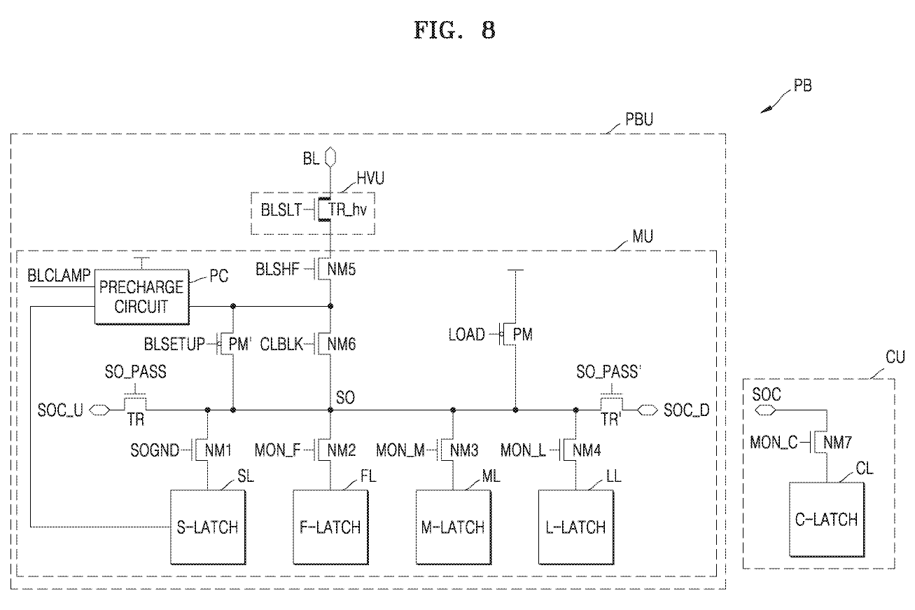

FIG. 8 is a view illustrating a page buffer PB according to an embodiment.

Referring to FIG. 8, the page buffer PB may correspond to an example of one of the page buffers PB11 to PB14 and PB21 to PB24 shown in FIG. 1. The page buffer PB may include a page buffer unit PBU and a cache unit CU. Because the cache unit CU includes a cache latch (C-LATCH) CL connected to a data input/output line, the cache unit CU may be adjacent to the data input/output line. Therefore, the page buffer unit PBU and the cache unit CU may be arranged apart from each other, and the page buffer PB may have a structure in which the page buffer unit PBU and the cache unit CU are separate from each other.

The page buffer unit PBU may include a main unit MU. The main unit MU may include main transistors in the page buffer PB. The page buffer unit PBU may further include a bit line select transistor TR_hv that is connected to a bit line BL and driven by a bit line select signal BLSLT. The bit line select transistor TR_hv may be implemented as a high-voltage transistor and may thus be provided in a different well region from the main unit MU, that is, in a high-voltage unit HVU.

The main unit MU may include a sensing latch (S-LATCH) SL, a force latch (F-LATCH) FL, a more-significant-bit latch (M-LATCH) ML, and a less-significant-bit latch (L-LATCH) LL. In some embodiments, the S-LATCH SL, the F-LATCH FL, the M-LATCH ML, or the L-LATCH LL may be referred to as a “main latch.” The main unit MU may further include a precharge circuit PC capable of controlling a precharge operation for the bit line BL or a sensing node SO based on a bit line clamping control signal BLCLAMP. In addition, the main unit MU may further include a transistor PM′ driven by a bit line setup signal BLSETUP.

During a read or program verify operation, the S-LATCH SL may store results of sensing data stored in a memory cell or results of sensing the threshold voltage of a memory cell. In addition, during a program operation, the S-LATCH SL may be used to apply a program bit line voltage or a program inhibit voltage to the bit line BL. The F-LATCH FL may be used to improve threshold voltage distribution during a program operation. For example, the F-LATCH FL may store force data. The force data may be initially set to ‘1,’ and then, when the threshold voltage of a memory cell enters a forcing region that is less than a target region, the force data may be inverted to ‘0.’ During a program execution operation, the force data may be used to control bit line voltage and narrower a program threshold voltage distribution.

The M-LATCH ML, the L-LATCH LL, and the C-LATCH CL may be used to store data input from the outside during a program operation, and may be referred to as data latches. When 3 bits of data are programmed in a memory cell, the 3 bits of data may be stored in the M-LATCH ML, the L-LATCH LL, and the C-LATCH CL, respectively. Until the programming of the memory cell is completed, the M-LATCH ML, the L-LATCH LL, and the C-LATCH CL may maintain the stored data. In addition, during a read operation, the C-LATCH CL may receive data read from a memory cell and transmitted from the S-LATCH SL, and may output the received data via the data input/output line to the outside of the page buffer PC, for example, to a page buffer decoder PBDEC11, PBDEC12, PBDEC21, or PBDEC22 shown in FIG. 10.

In addition, the main unit MU may further include first to fourth transistors NM1 through NM4. The first transistor NM1 may be connected between the sensing node SO and the S-LATCH SL and may be driven by a ground control signal SOGND. The second transistor NM2 may be connected between the sensing node SO and the F-LATCH FL and may be driven by a forcing monitoring signal MON_F. The third transistor NM3 may be connected between the sensing node SO and the M-LATCH ML and may be driven by a more-significant-bit monitoring signal MON_M. The fourth transistor NM4 may be connected between the sensing node SO and the L-LATCH LL and may be driven by a less-significant-bit monitoring signal MON_L.

In addition, the main unit MU may further include fifth and sixth transistors NM5 and NM6 connected in series to each other between the bit line select transistor TR_hv and the sensing node SO. The fifth transistor NM5 may be driven by a bit line shut-off signal BLSHF, and the sixth transistor NM6 may be driven by a bit line connection control signal CLBLK. In addition, the main unit MU may further include a precharge transistor PM. The precharge transistor PM is connected to the sensing node SO, is driven by a load signal LOAD, and precharges the sensing node SO to a precharge level during a precharge period.

In the current embodiment, the main unit MU may further include a pair of pass transistors connected to the sensing node SO, that is, first and second pass transistors TR and TR′ connected to the sensing node SO. The first pass transistor TR may be driven based on a first pass control signal SO_PASS, and the second pass transistor TR’ may be driven based on a second pass control signal SO_PASS’. For example, the first pass transistor TR may be connected between a first terminal SOC_U and the sensing node SO, and the second pass transistor TR′ may be between the sensing node SO and a second terminal SOC_D.

For example, when the page buffer unit PBU corresponds to the second page buffer unit PBU12 shown in FIG. 7, the first terminal SOC_U may be connected to an end of a pass transistor included in the first page buffer unit PBU11, and the second terminal SOC_D may be connected to an end of a pass transistor included in the third page buffer unit PBU13. In this manner, the sensing node SO may be electrically connected to the binding sensing node SOC via pass transistors included in each of the second to nth page buffer units PBU12 through PBU1n.

During a program operation, the page buffer PB may verify whether programming is completed in a memory cell selected from memory cells included in an NAND string connected to the bit line BL. For example, during the verification of programming, the page buffer PB stores, in the S-LATCH SL, data sensed via the bit line BL. The M-LATCH ML and the L-LATCH LL in which target data is stored may be set according to the sensed data stored in the S-LATCH SL. For example, when the sensed data indicates that programming is completed, the M-LATCH ML and the L-LATCH LL may be switched to a program inhibit setup for a memory cell selected in a subsequent program loop. The C-LATCH CL may temporarily store input data that is provided from the outside. During a program operation, target data stored in the C-LATCH CL may be stored in the M-LATCH ML and the L-LATCH LL.

Referring to FIGS. 6 and 8, the structures 63 to 66 shown in FIG. 6 may be connected to bit line select transistors TR_hv included in the page buffers PB11, PB12, PB21, and PB22.

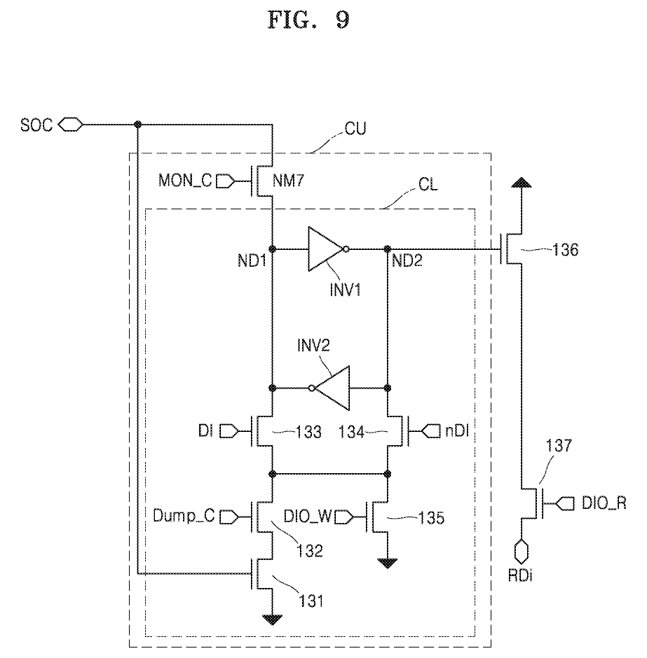

FIG. 9 is a circuit diagram illustrating the cache unit CU according to an embodiment.

Referring to FIGS. 8 and 9, the cache unit CU may include a monitor transistor NM7 and the C-LATCH CL. The C-LATCH CL may include first and second inverters INV1 and INV2, a dump transistor 132, and transistors 131, 133, 134, and 135. The monitor transistor NM7 may be driven based on a cache monitoring signal MON_C and may control connection between the binding sensing node SOC and the C-LATCH CL.

The first inverter INV1 may be connected between a first node ND1 and a second node ND2, and the second inverter INV2 may be connected between the second node ND2 and the first node ND1. The first and second inverters INV1 and INV2 may form a latch. The transistor 131 may include a gate connected to the binding sensing node SOC. The dump transistor 132 may be driven by a dump signal Dump_C, and may transmit data stored in the C-LATCH CL to a main latch, for example, to the S-LATCH SL in the page buffer unit PBU. The transistor 133 may be driven by a data signal DI, the transistor 134 may be driven by a data inversion signal nDI, and the transistor 135 may be driven by a write control signal DIO_W. When the write control signal DIO_W is activated, voltage levels of the first and second nodes ND1 and ND2 may be determined based on the data signal DI and the data inversion signal nDI.

The cache unit CU may be connected to an input/output terminal RDi via transistors 136 and 137. The transistor 136 may include a gate connected to the second node ND2, and may be turned on or off based on a voltage level of the second node ND2. The transistor 137 may be driven by a read control signal DIO_R. When the read control signal DIO_R is activated and the transistor 137 is turned on, the voltage level of the input/output terminal RDi may be determined as ‘1’ or ‘0’ based on a state of the C-LATCH CL.

FIG. 10 is a block diagram illustrating a page buffer circuit 210 and a data input/output circuit 250 according to an embodiment.

Referring to FIG. 10, the page buffer circuit 210 may include page buffers PB11 to PB14 and PB21 to PB24, page buffer decoders PBDEC11, PBDEC12, PBDEC21, and PBDEC22, and page buffer drivers PBDRV1 and PBDRV2. The page buffers PB11 to PB14, the page buffer decoders PBDEC11 and PBDEC12, and the page buffer driver PBDRV1 may be arranged in the circuit region 261 shown in FIG. 6. The page buffers PB21 to PB24, the page buffer decoders PBDEC21 and PBDEC22, and the page buffer driver PBDRV2 may be arranged in the circuit region 262 shown in FIG. 6. The number of page buffers, the number of page buffer decoders, and the number of page buffer drivers included in the page buffer circuit 210 are not limited thereto.

The page buffers PB11 to PB14 and PB21 to PB24 may be connected to the page buffer decoders PBDEC11 to PBDEC22 through cache latches. During a read operation, data sensed from memory cells may be stored in the cache latches, and the data stored in the cache latches may be provided to the data input/output circuit 250 through the page buffer decoders PBDEC11, PBDEC12, PBDEC21, and PBDEC22 and the page buffer drivers PBDRV1 and PBDRV2.

Each of the page buffer decoders PBDEC11 and PBDEC12 may select a page buffer based on a column address Y_ADDR and connect the selected page buffer to the page buffer driver PBDRV1. Each of the page buffer decoders PBDEC21 and PBDEC22 may select a page buffer based on a column address Y_ADDR and connect the selected page buffer to the page buffer driver PBDRV2.

The page buffer driver PBDRV1 may include transistors 201a, 202a, and 203a, and an inverter 204a. A first terminal of the transistor 201a may be connected to the page buffer decoders PBDEC11 and PBDEC12, a second terminal of the transistor 201a may be connected to a first terminal of the transistor 202a, and a control signal ctrl11 may be received through a gate terminal of the transistor 201a. A second terminal of the transistor 202a may be connected to a ground node, and a control signal ctrl12 may be received through a gate terminal of the transistor 202a. A first terminal of the transistor 203a may be connected to a supply voltage node, a second terminal of the transistor 203a may be connected to the second terminal of the transistor 201a, and a gate terminal of the transistor 203a may be connected to an output node of the inverter 204a. An input terminal of the inverter 204a may be connected to the second terminal of the transistor 203a, and the output terminal of the inverter 204a may be connected to the data input/output circuit 250. The page buffer driver PBDRV1 may receive data though the page buffer decoders PBDEC11 and PBDEC12, amplify the data through the transistor 203a and the inverter 204a, provide the amplified data to the data input/output circuit 250.

The page buffer driver PBDRV2 may include transistors 201b, 202b, and 203b, and an inverter 204b, and the description of the page buffer driver PBDRV1 may be applied to the page buffer driver PBDRV2.

Referring to FIGS. 1 and 10, page buffers PB11 and PB13 may be connected to bit lines BL11 and BL12 included in a first bit line group, and the page buffers PB12 and PB14 may be connected to bit lines BL21 and BL22 included in a second bit line group. That is, the page buffer driver PBDRV1 may be commonly connected to both the first sub-plane 110 and the second sub-plane 120. Furthermore, the page buffers PB21 and PB23 are connected to bit lines BL13 and BL14 included in the first bit line group, and the page buffers PB22 and PB24 may be connected to bit lines BL23 and BL24 included in the second bit line group. That is, the page buffer driver PBDRV2 may also be commonly connected to both the first sub-plane 110 and the second sub-plane 120. Therefore, even during a read operation on only one of the first sub-plane 110 and the second sub-plane 120, both the page buffer drivers PBDRV1 and PBDRV2 may be used, thereby improving I/O performance.

The data input/output circuit 250 may output data received from the page buffer drivers PBDRV1 and PBDRV2 to external components through data pins D1 to Dn. The data pins D1 to Dn may also be referred to as DQ pins.

In one or more embodiments, a memory device may include a first half-cell-array (e.g., the first sub-plane 110) connected a plurality of first bit lines (e.g., BL11-BL14), a second half-cell-array (the second sub-plane 120) connected a plurality of second bit lines (e.g., BL21-BL24), a first input/output sense amplifier (IOSA) (e.g., PBDRV1 in the page buffer circuit 210) electrically connected to a plurality of first bit lines (e.g., BL11, BL12)

and a plurality of second bit lines (e.g., BL21, BL22), a second input/output sense amplifier (IOSA) (e.g., PBDRV2 in the page buffer circuit 210) electrically connected to a plurality of first bit lines (e.g., BL13, BL14) and a plurality of second bit lines (e.g., BL23, BL24), and an additional metal lines (e.g., extension lines L1-L4) disposed a metal layer (e.g., wiring layer M2 or wiring layer within the peripheral circuit region 92) above or below a metal layer (e.g., wiring layer M1) in which the bit lines (e.g., BL11-BL14 and BL21-BL24) are formed. The bit lines of the first half-cell-array may be alternately electrically connected to the first IOSA and the second IOSA, the bit lines of the second half-cell-array may be alternately electrically connected to the first IOSA and the second IOSA, the bit lines of the second half-cell-array may be electrically connected to the first IOSA through the additional metal lines; and the bit lines of the first half-cell-array may be electrically connected to the second IOSA through the additional metal lines. During a read operation on the first half-cell-array, both the first IOSA and the second IOSA may be driven, such that an I/O speed for the read operation is substantially equal to an I/O speed of a read operation on the first and second half-cell-arrays together.

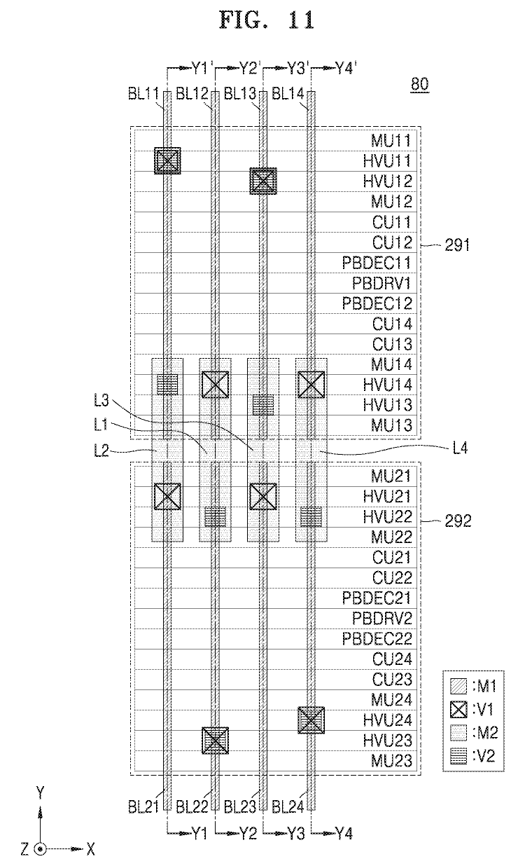

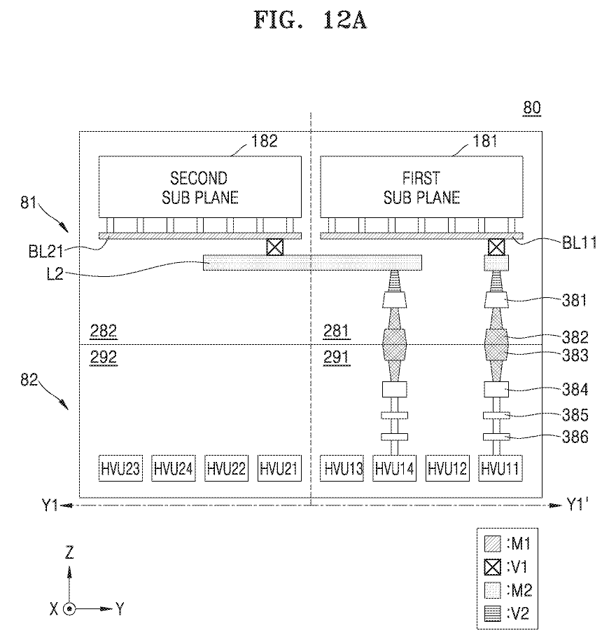

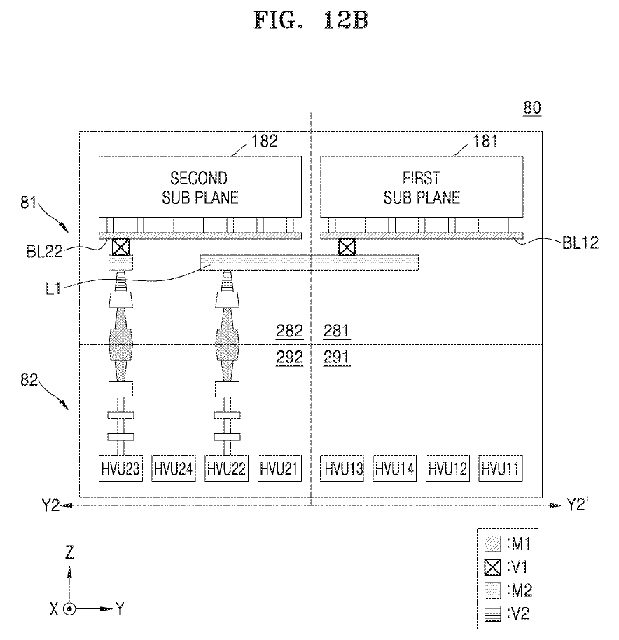

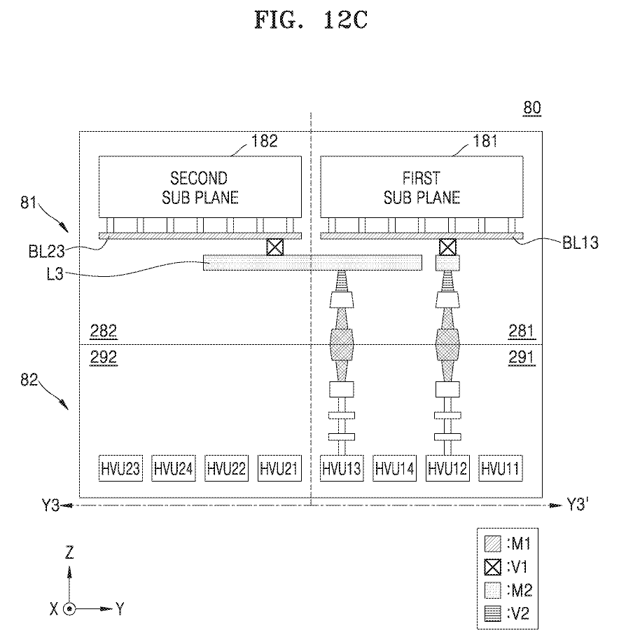

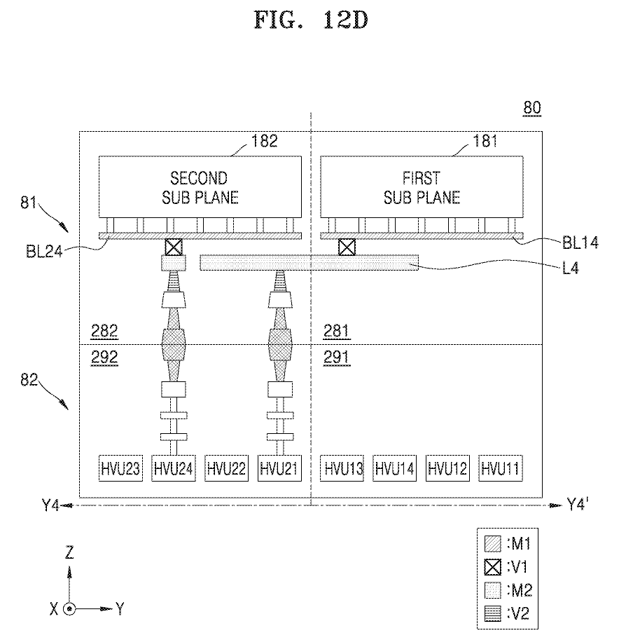

FIG. 11 is a plan view illustrating a memory device 80 according to an embodiment. FIGS. 12A -12D are cross-sectional views illustrating the memory device 80 according to embodiments. For example, FIG. 12A is a cross-sectional view taken along line Y1-Y1′ of FIG. 11, FIG. 12B is a cross-sectional view taken along line Y2-Y2′ of FIG. 11, FIG. 12C is a cross-sectional view taken along line Y3-Y3′ of FIG. 11, and FIG. 12D is a cross-sectional view taken along line Y4-Y4′ of FIG. 11.

Referring to FIGS. 11 and 12A -12D, the memory device 80 may include bit lines BL11 to BL14, bit lines BL21 to BL24, and first to fourth extension lines L1 to L4 arranged in a memory cell region 81. The memory device 80 may include a first sub-plane 181 provided in a first sub-plane region 281 and a second sub-plane 182 provided in a second sub-plane region 282.

The memory device 80 may include main units MU11 to MU14 and MU21 to MU24, high-voltage units HVU11 to HVU14 and HVU21 to HVU24, cache units CU11 to CU14 and CU21 to CU24, page buffer decoders PBDEC11, PBDEC12, PBDEC21, and PBDEC22, and page buffer drivers PBDRV1 and PBDRV2, which are arranged in a peripheral circuit region 82. The main unit MU11, the high-voltage unit HVU11, and the cache unit CU11 may be included in a page buffer PB11; the main unit MU12, the high- voltage unit HVU12, and the cache unit CU12 may be included in a page buffer PB12; the main unit MU13, the high-voltage unit HVU13, and the cache unit CU13 may be included in a page buffer PB13; and the main unit MU14, the high-voltage unit HVU14, and the cache unit CU14 may be included in a page buffer PB14. The main unit MU21, the high-voltage unit HVU21, and the cache unit CU21 may be included in a page buffer PB21; the main unit MU22, the high-voltage unit HVU22, and the cache unit CU22 may be included in a page buffer PB22; the main unit MU23, the high-voltage unit HVU23, and the cache unit CU23 may be included in a page buffer PB23; and the main unit MU24, the high-voltage unit HVU24, and the cache unit CU24 may be included in a page buffer PB24.

The page buffers PB11 to PB14, the page buffer decoders PBDEC11 and PBDEC12, and the page buffer driver PBDRV1 may be arranged in a circuit region 291, and the page buffers PB21 to PB24, the page buffer decoders PBDEC21 and PBDEC22, and the page buffer driver PBDRV2 may be arranged in a circuit region 292.

Each of the bit lines BL11 to BL14 and BL21 to BL24 may extend in a first wiring layer M1 in a second horizontal direction. The bit lines BL11 to BL14, which are included in a first bit line group, may be apart from the bit lines BL21 to BL24, which are included in a second bit line group, in the second horizontal direction.

Referring to FIGS. 11, 12B, and 12D, the bit lines BL12 and BL14 may be respectively connected to the first and fourth extension lines L1 and L4 through vias that are formed in a first via layer V1. The first and fourth extension lines L1 and L4 may extend in the second horizontal direction. The first and fourth extension lines L1 and L4 may extend to at least portions that vertically and respectively overlap the high-voltage units HVU22 and HVU21 arranged in the circuit region 292. The first and fourth extension lines L1 and L4 may be respectively connected to high-voltage transistors formed in the high-voltage units HVU22 and HVU21 through vias that are formed in a second via layer V2.

Referring to FIGS. 11, 12A, and 12C, the bit lines BL21 and BL23 may be respectively connected to the second and third extension lines L2 and L3 through vias that are formed in the first via layer V1. The second and third extension lines L2 and L3 may extend in the second horizontal direction. The second and third extension lines may extend to at least portions that vertically and respectively overlap the high-voltage units HVU14 and HVU13 arranged in the circuit region 291. The second and third extension lines L2 and L3 may be respectively connected to high-voltage transistors formed in the high-voltage units HVU14 and HVU13 through vias that are formed in the second via layer V2.

Referring to FIGS. 11, 12A, and 12C, the bit lines BL11 and BL13 may be respectively connected to high-voltage transistors of the high-voltage units HVU11 and HVU12 through structures that are vertically formed through the first via layer V1, the second wiring layer M2, and the second via layer V2 (e.g., see the structure 63 shown in FIG. 6).

Referring to FIGS. 11, 12B, and 12D, the bit lines BL22 and BL24 may be respectively connected to high-voltage transistors of the high-voltage units HVU23 and HVU24 through structures that are vertically formed through the first via layer V1, the second wiring layer M2, and the second via layer V2 (e.g., see the structure 65 shown in FIG. 6).

Referring to FIG. 12A, the memory cell region 81 may include the first wiring layer M1, the first via layer V1, the second wiring layer M2, and the second via layer V2. In addition, the memory cell region 81 may include a metal line 381 and a first bonding metal 382 that are formed above the second via layer V2. The number of metal wiring layers formed in the memory cell region 81 is not limited thereto. The first bonding metal 382 may be electrically connected to a second bonding metal 383 of the peripheral circuit region 82 by a bonding method. The peripheral circuit region 82 may include sequentially stacked metal lines 384, 385, and 386. A high-voltage unit and a bit line may be connected to each other through the metal lines 384, 385, and 386. The number of metal wiring layers is not limited thereto.

Referring to FIGS. 11 and 12A -12D, because the bit lines BL11 to BL14 and BL21 to BL24 are connected to the page buffers PB11 to PB14 and PB21 to PB24 through the first to fourth extension lines L1 to L4 formed in the second wiring layer M2, the memory device 80 may use both the page buffer drivers PBDRV1 and PBDRV2 regardless of the size of read data during a read operation.

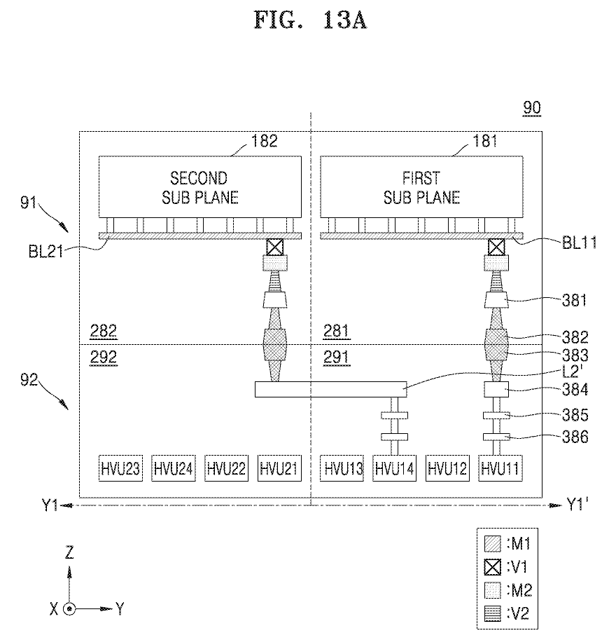

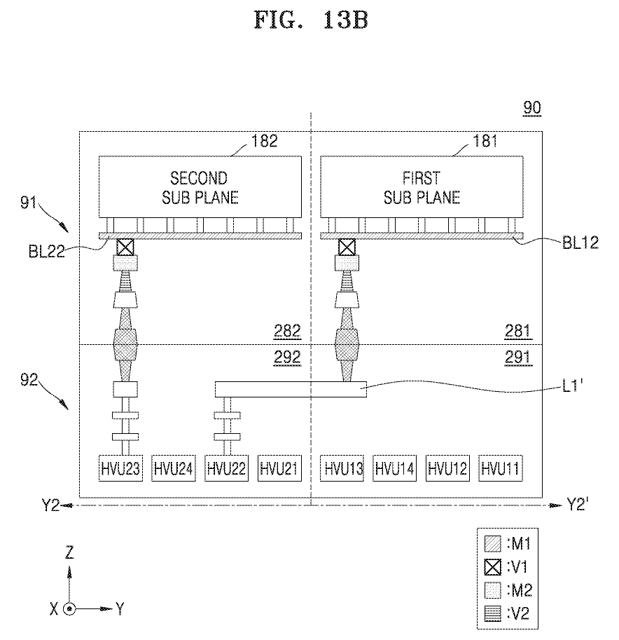

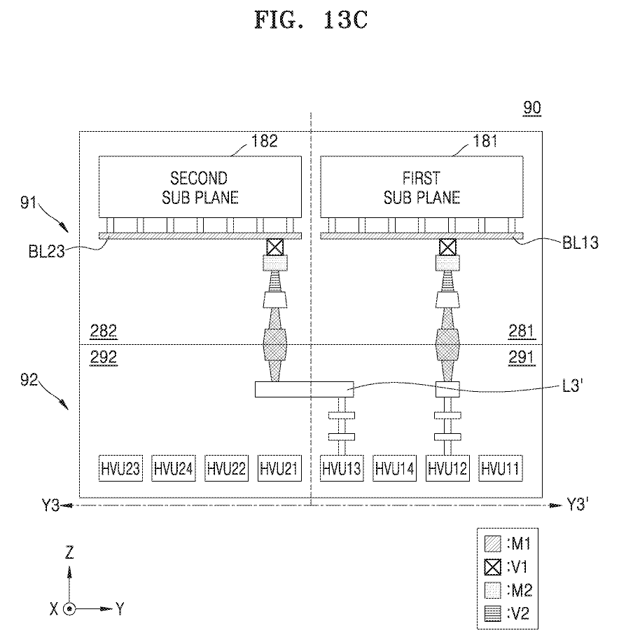

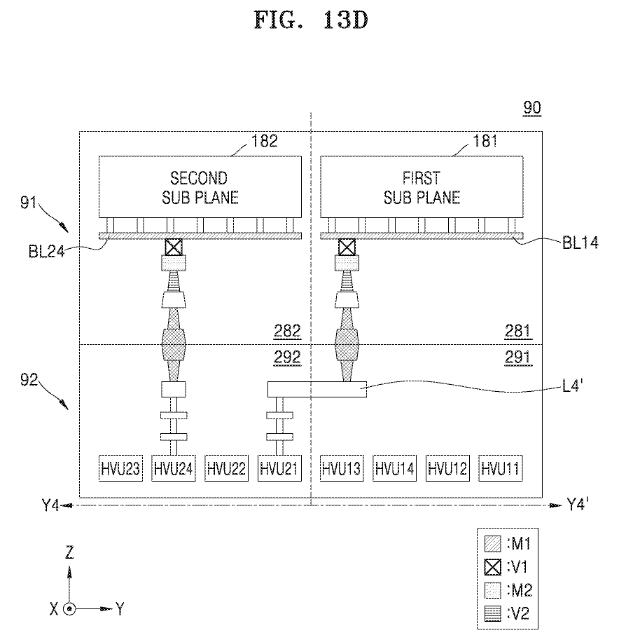

FIGS. 13A -13D are cross-sectional views illustrating a memory device 90 according to embodiments.

The memory device 90 may include a memory cell region 91 and a peripheral circuit region 92. The same description as that given above may be omitted when describing the memory cell region 91 and the peripheral circuit region 92.

Referring to FIG. 13A in comparison with FIG. 12A, a second extension line L2’ may extend from a circuit region 292 to a circuit region 291 within the peripheral circuit region 92. The bit line BL21 may be connected to a high-voltage transistor of the high-voltage unit HVU14 through the second extension line L2’.

Referring to FIG. 13B in comparison with FIG. 12B, within the peripheral circuit region 92, a first extension line L1’ may extend from the circuit region 291 to the circuit region 292. A bit line BL12 may be connected to a high-voltage transistor of a high-voltage unit HVU22 through the first extension line L1’.

Referring to FIG. 13C in comparison with FIG. 12C, a third extension line L3’ may extend from the circuit region 292 to the circuit region 291 within the peripheral circuit region 92. A bit line BL23 may be connected to a high-voltage transistor of a high-voltage unit HVU13 through the third extension line L3’.

Referring to FIG. 13D in comparison with FIG. 12D, a fourth extension line L4’ may extend from the circuit region 291 to the circuit region 292 within the peripheral circuit region 92. A bit line BL14 may be connected to a high-voltage transistor of a high-voltage unit HVU21 through the fourth extension line L4’.

Although the first to fourth extension lines L1’ to L4’ are illustrated as being formed in a wiring layer of a metal line 384, embodiments are not limited thereto. The first to fourth extension lines L1’ to L4’ may be formed in any wiring layer within the peripheral circuit region 92.

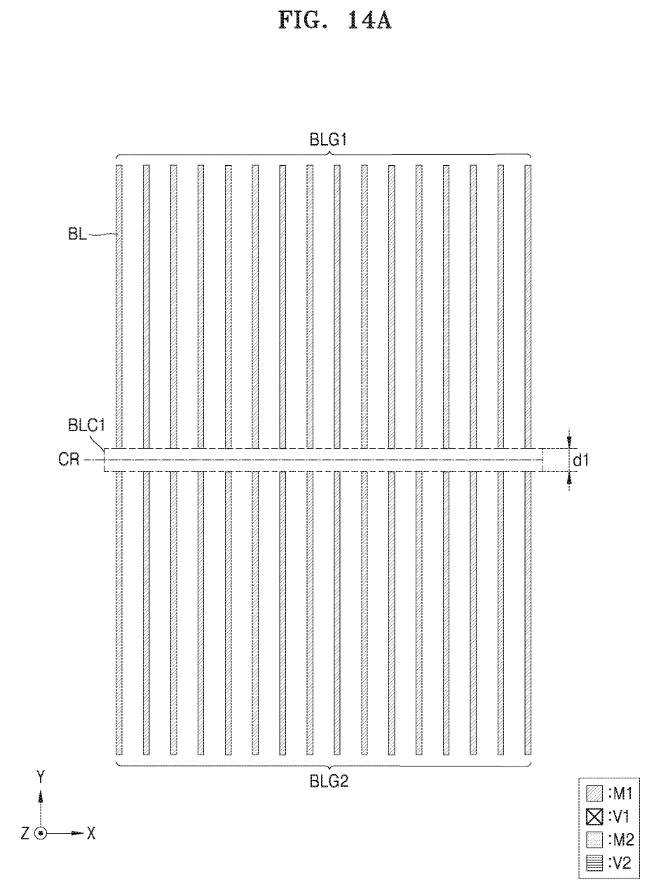

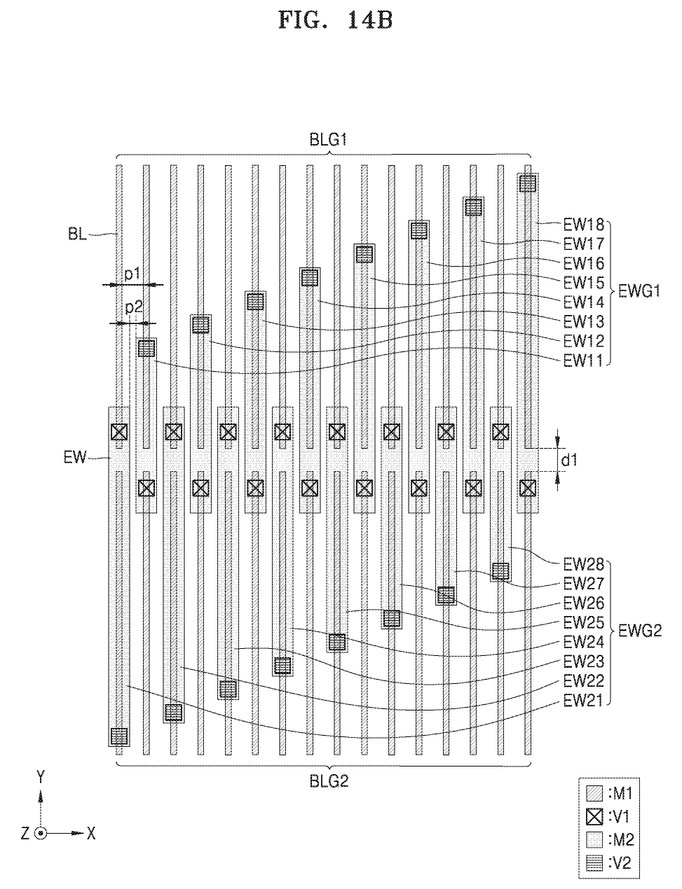

FIGS. 14A and 14B illustrate example layouts showing an arrangement of bit lines BL and extension lines EW according to embodiments. The bit lines BL and the extension lines EW shown in FIGS. 14A and 14B may be arranged in a memory cell region (e.g., see the memory cell region 81 shown in FIG. 12A). In FIGS. 14A to 16B, it is assumed that the memory cell region is vertically flipped. Therefore, the term “upper” may refer to an -Z axis direction in this context.

Referring to FIG. 14A, a plurality of bit lines BL, each extending in a second horizontal direction, may be spaced apart from each other in a first horizontal direction. The bit lines BL are divided by a bit line cut region BLC1, thereby forming two separate bit line groups, a first bit line group BLG1 and a second bit line group BLG2. Bit lines BL of the first bit line group BLG1 may be connected to a first sub-plane, and bit lines BL of the second bit line group BLG2 may be connected to a second sub-plane. The first bit line group BLG1 and the second bit line group BLG2 may be separated by a first separation distance d1. In other words, all the bit lines BL may be cut along a cut row CR extending in the first horizontal direction to form the first bit line group BLG1 and the second bit line group BLG2. The bit lines BL included in the first bit line group BLG1 may have the same length, and the bit lines BL included in the second bit line group BLG2 may also have the same length.

Referring to FIG. 14B, extension lines EW each extending in the second horizontal direction may be spaced apart from each other in the first horizontal direction. The extension lines EW may be aligned with the bit lines BL of the first bit line group BLG1 and the bit lines BL of the second bit line group BLG2. The extension lines EW may overlap the bit line cut region BLC formed along the cut row CR.

In regions vertically overlapping a subset of the bit lines BL included in the second bit line group BLG2, extension lines EW11 to EW18 included in a first extension line group EWG1 may be connected to the subset of the bit lines BL through vias of a first via layer V1. The extension lines EW11 to EW18 may extend across the bit line cut region BLC1 into regions vertically overlapping a subset of the bit lines BL included in the first bit line group BLG1. In the regions vertically overlapping the subset of the bit lines BL included in the first bit line group BLG1, the extension lines EW11 to EW18 may be connected to different page buffers included in a first page buffer group through vias of a second via layer V2.

In regions vertically overlapping the remainder of the bit lines BL included in the first bit line group BLG1, extension lines EW21 to EW28 included in a second extension line group EWG2 may be connected to the remainder of the bit lines BL included in the first bit line group BLG1 through vias of the first via layer V1. The extension lines EW21 to EW28 may extend across the bit line cut region BLC1 into regions vertically overlapping the remainder of the bit lines BL included in the second bit line group BLG2. In the regions vertically overlapping the remainder of the bit lines BL included in the second bit line group BLG2, the extension lines EW21 to EW28 may be connected to different page buffers included in a second page buffer group through vias of the second via layer V2.

The bit lines BL may be spaced apart from each other with a first distance p1 in the first horizontal direction, and the extension lines EW may be spaced apart from each other with a second distance p2 in the first horizontal direction. When the width of the extension lines EW is equal to the width of the bit lines BL, the first distance p1 and the second distance p2 may be the same. However, when the width of the extension lines EW is greater than the width of the bit lines BL, the second distance p2 may be less than the first distance p1. Therefore, mutual interference may occur between extension lines EW that are adjacent to each other in the first horizontal direction, which may violate design rules.

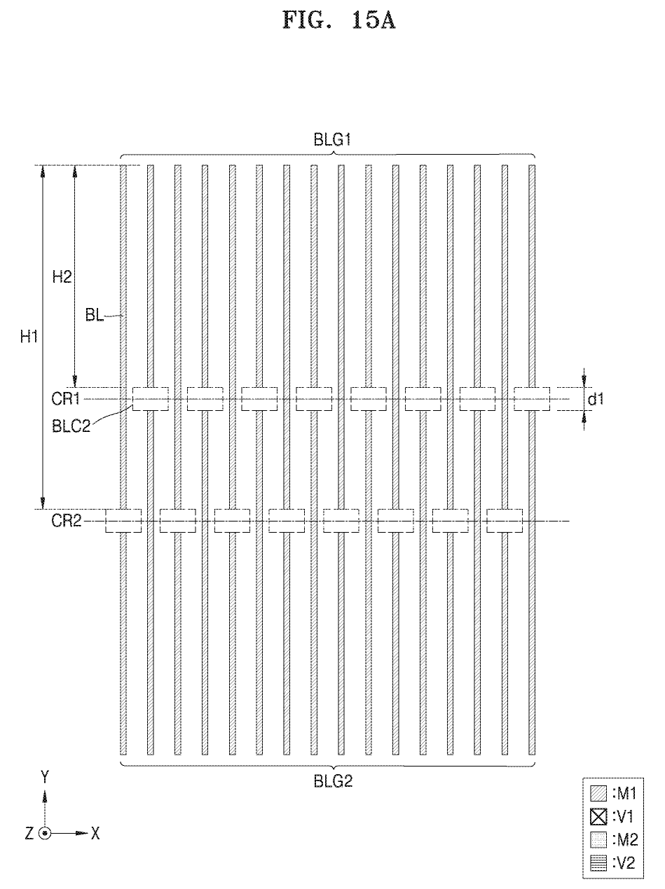

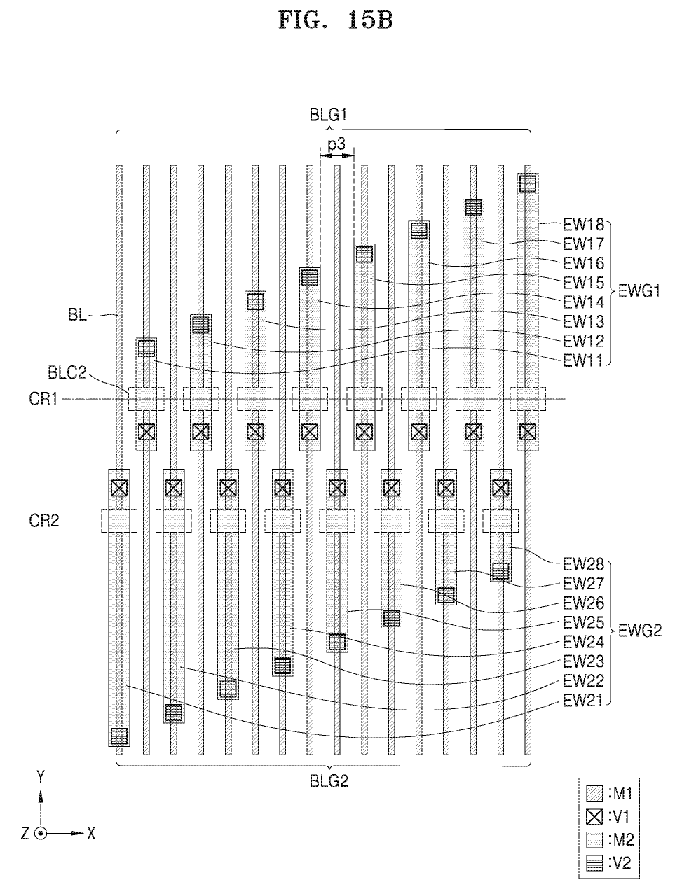

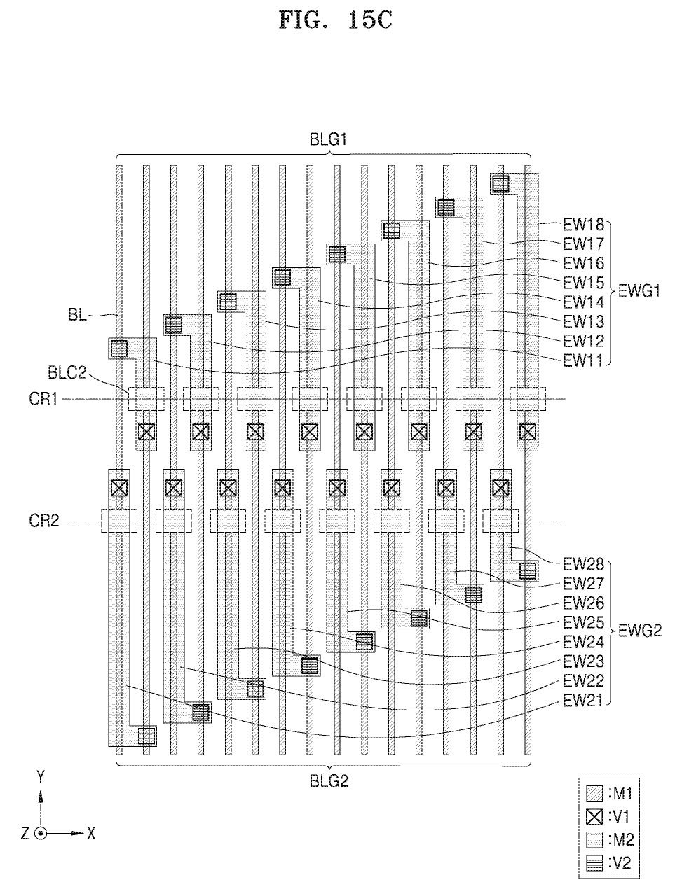

FIGS. 15A -15C are layouts illustrating an arrangement of bit lines BL and extension lines EW according to an embodiment.

Referring to FIG. 15A, a plurality of bit lines BL each extending in a second horizontal direction may be spaced apart from each other in a first horizontal direction. The bit lines BL may be divided other by bit line cut regions BLC2, and thus, a first bit line group BLG1 and a second bit line group BLG2 may be formed. Bit lines BL of the first bit line group BLG1 may be connected to a first sub-plane, and bit lines BL of the second bit line group BLG2 may be connected to a second sub-plane. The first bit line group BLG1 and the second bit line group BLG2 may be apart from each other by a first separation distance d1.

One of every two bit lines BL that are adjacent to each other in the first horizontal direction may be cut along a first cut row CR1 extending in the first horizontal direction, and the remaining bit lines BL that are not cut along the first cut row CR1 may be cut along a second cut row CR2 extending in the first horizontal direction. In this manner, the first bit line group BLG1 and the second bit line group BLG2 may be formed. The bit lines BL included in the first bit line group BLG1 are arranged such that bit lines BL having a first length H1 and bit lines BL having a second length H2 may be alternately arranged in the first horizontal direction.

Referring to FIG. 15B, extension lines EW11 to EW18 included in a first extension line group EWG1 may be arranged at positions overlapping the bit line cut regions BLC2 formed along the first cut row CR1.

In regions vertically overlapping a subset of the bit lines BL included in the second bit line group BLG2, the extension lines EW11 to EW18 included in the first extension line group EWG1 may be connected to the subset of the bit lines BL included in the second bit line group BLG2 through vias of a first via layer V1. The extension lines EW11 to EW18 may extend across the bit line cut regions BLC2 to regions vertically overlapping with a subset of the bit lines BL included in the first bit line group BLG1. In the regions vertically overlapping the subset of the bit lines BL included in the first bit line group BLG1, the extension lines EW11 to EW18 may be connected to different page buffers included in a first page buffer group through vias of a second via layer V2.

In regions vertically overlapping the remainder of the bit lines BL included in the first bit line group BLG1, extension lines EW21 to EW28 included in a second extension line group EWG2 may be connected to the remainder of the bit lines BL included in the first bit line group BLG1 through vias of the first via layer V1. The extension lines EW21 to EW28 may extend across the bit line cut regions BLC2 to regions vertically overlapping the remainder of the bit lines BL included in the second bit line group BLG2. In the regions vertically overlapping the remainder of the bit lines BL included in the second bit line group BLG2, the extension lines EW21 to EW28 may be connected to different page buffers included in a second page buffer group through vias of the second via layer V2

In other words, the bit lines BL are cut along two cut rows, that is, the first and second cut rows CR1 and CR2 extending in the first horizontal direction and spaced apart from each other in the second horizontal direction, in such a manner such that one of every two bit lines BL that are adjacent to each other in the first horizontal direction may be cut along the first cut row CR1, and the remaining one may be cut along the second cut row CR2. Thus, the first bit line group BLG1 and the second bit line group BLG2 may be formed.

The first extension line group EWG1 and the second extension line group EWG2 may be apart from each other in the second horizontal direction. As a result, extension lines that are adjacent to each other in the first horizontal direction may be spaced apart from each other with a third distance p3 in the first horizontal direction. The third distance p3 may be greater than the second distance p2 (see FIG. 14B). Therefore, interference between extension lines may be reduced, and the arrangement of extension lines may satisfy design rules.

However, because the size of the bit line cut regions BLC2 is smaller than the size of the bit line cut region BLC1 (see FIG. 14A), processibility may deteriorate. For example, because the length of each of the bit line cut regions BLC2 in the first horizontal direction is less than the length of the bit line cut region BLC1 in the first horizontal direction, processibility may deteriorate.

Referring to FIG. 15C, each of the extension lines may have an L-shape. A bottom portion of the L-shape may be connected to a page buffer through a via of the second via layer V2.

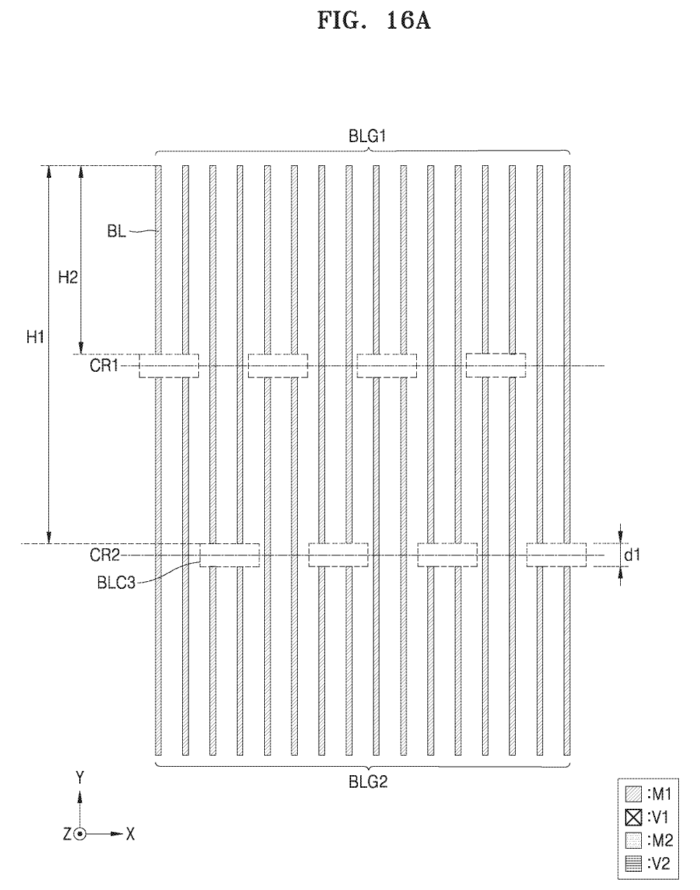

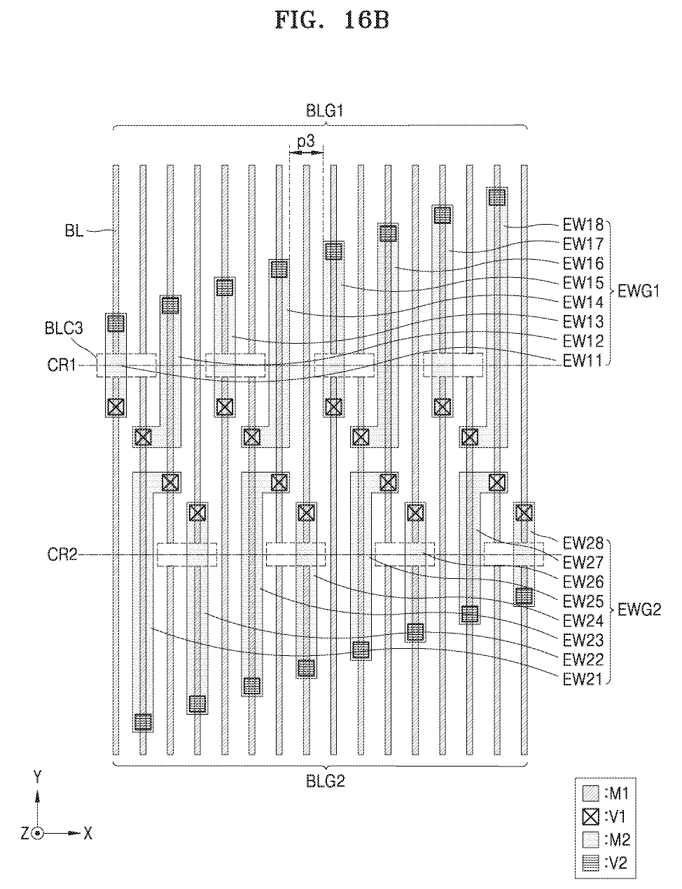

FIGS. 16A and 16B are layouts illustrating an arrangement of bit lines and extension lines according to an embodiment.

Referring to FIG. 16A, a plurality of bit lines BL each extending in a second horizontal direction may be spaced apart from each other in a first horizontal direction. The bit lines BL are divided by bit line cut regions BLC3, thereby forming a first bit line group BLG1 and a second bit line group BLG2. Bit lines BL of the first bit line group BLG1 may be connected to a first sub-plane, and bit lines BL of the second bit line group BLG2 may be connected to a second sub-plane. The first bit line group BLG1 and the second bit line group BLG2 may be apart from each other by a first separation distance d1.

Two consecutive bit lines BL out of every four consecutive bit lines BL arranged in the first horizontal direction may be cut along a first cut row CR1 extending in the first horizontal direction, and the remaining two bit lines BL that are not cut along the first cut row CR1 among the same four consecutive bit lines BL may be cut along a second cut row CR2 extending in the first horizontal direction. In this manner, the first bit line group BLG1 and the second bit line group BLG2 may be formed. The bit lines BL included in the first bit line group BLG1 are arranged such that two bit lines having a first length H1 and two bit lines having a second length H2 may be alternately repeated in the first horizontal direction.

Referring to FIG. 16B, extension lines EW11 to EW18 included in a first extension line group EWG1 may be connected to the bit lines BL included in the second bit line group BLG2 through vias of a first via layer V1. The extension lines EW11 to EW18 may be connected to different page buffers included in a first page buffer group through vias of a second via layer V2.

Extension lines EW21 to EW28 included in a second extension line group EWG2 may be connected to the bit lines BL included in the first bit line group BLG1 through vias of the first via layer V1. The extension lines EW21 to EW28 may be connected to different page buffers included in a second page buffer group through vias of the second via layer V2.

Extension lines that are adjacent in the first horizontal direction may be spaced apart from each other in the first horizontal direction with a third distance p3. The third distance p3 may be greater than the second distance p2 (see FIG. 14B). This increased spacing may reduce interference between extension lines and ensure that the layout of extension lines complies with design rules. Furthermore, because the size of the bit line cut regions BLC3 is greater than the size of the bit line cut regions BLC2 (see FIGS. 15B and 15C), processibility may be improved. For example, because the length of each of the bit line cut regions BL3 in the first horizontal direction is greater than the length of each of the bit line cut regions BL2 in the first horizontal direction, overall process efficiency may be improved.

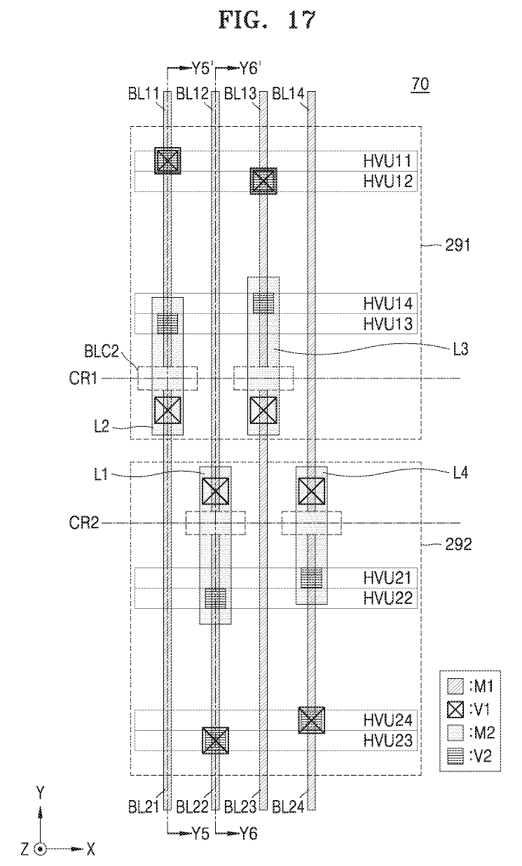

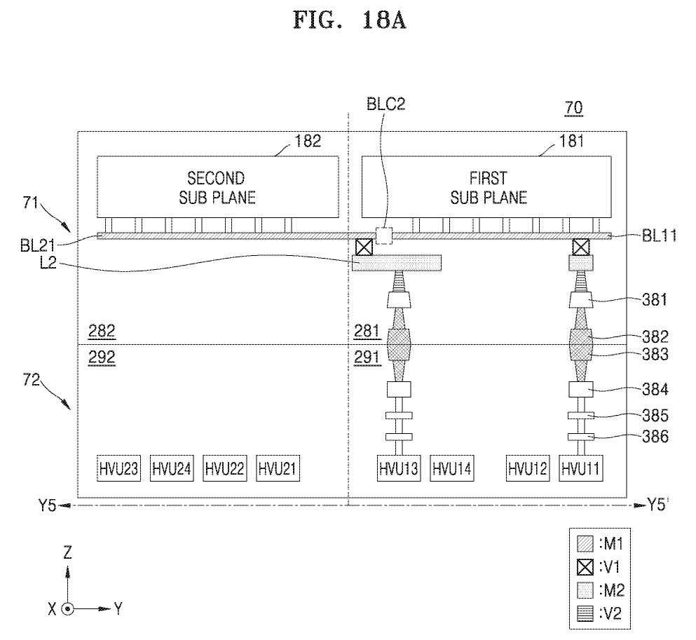

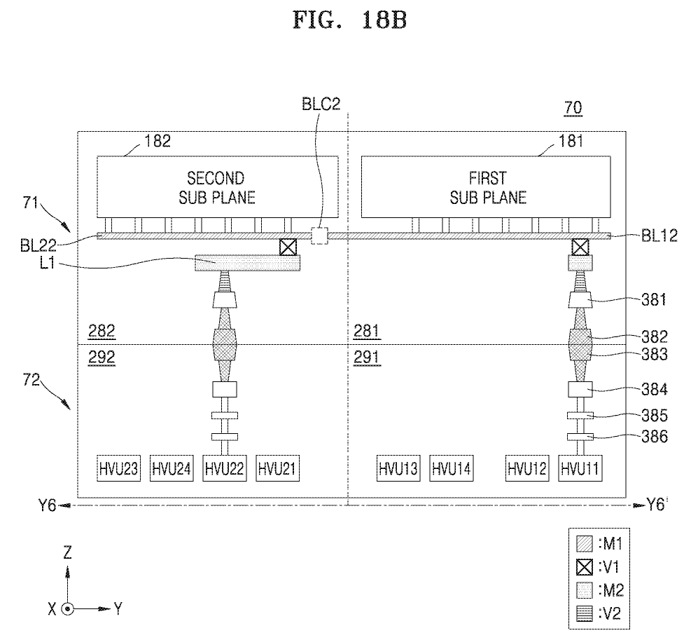

FIG. 17 is a plan view illustrating a memory device 70 according to an embodiment. FIGS. 18A and 18B are cross-sectional views illustrating the memory device 70 according to embodiments. For example, FIG. 18A is a cross-sectional view taken along line Y5-Y5’ of FIG. 17, and FIG. 18B is a cross-sectional view taken along line Y6-Y6’ of FIG. 17. The description given above with reference to the drawings may also be applied to FIGS. 17 -18B.

Bit lines BL11 to BL14 and BL21 to BL24 may extend in a first wiring layer M1 in a second horizontal direction. The bit lines BL11 to BL14, which is included in a first bit line group, and the bit lines BL21 to BL24, which is included in a second bit line group, may be arranged apart from each other in the second horizontal direction.

The bit lines BL21 and BL23 may extend in the second horizontal direction to portions overlapping a first sub-plane region 281. The bit lines BL21 and BL23 may extend in the second horizontal direction to portions overlapping a circuit region 291. Referring also to FIG. 15A, the bit lines BL21 and BL23 may be apart from the bit lines BL11 and BL13 by the first separation distance d1 in the second horizontal direction.

The bit lines BL12 and BL14 may extend in the second horizontal direction to portion overlapping a second sub-plane region 282. The bit lines BL12 and BL14 may extend in the second horizontal direction to portions overlapping a circuit region 292. Referring also to FIG. 15A, the bit lines BL12 and BL14 may be apart from the bit lines BL22 and BL24 by the first separation distance d1 in the second horizontal direction.

Although not shown in FIGS. 17 -18B, referring to FIGS. 16A and 16B, among the bit lines BL included in the first bit line group BLG1, the bit lines BL adjacent to the bit line cut regions BLC3 formed along the second cut row CR2 may extend in the second horizontal direction to portions overlapping the second sub-plane region 282 or the circuit region 292. Among the bit lines BL included in the second bit line group BLG2, the bit lines BL adjacent to the bit line cut regions BLC3 formed along the first cut row CR1 may extend in the second horizontal direction to portions overlapping the first sub-plane region 281 or the circuit region 291.

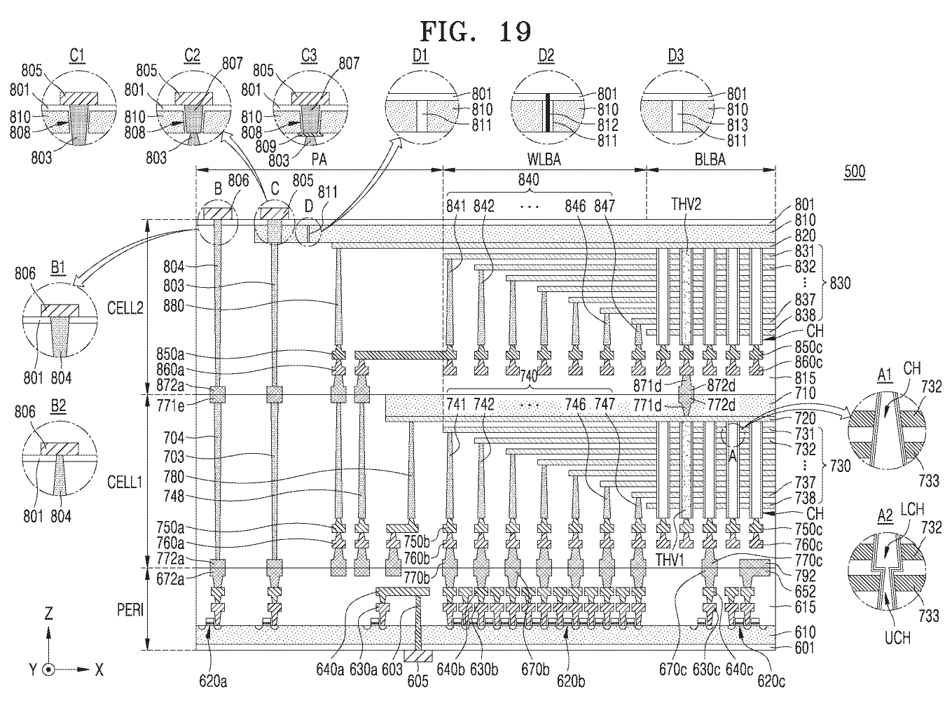

FIG. 19 is a view illustrating a memory device 500 according to some embodiments.

Referring to FIG. 19, the memory device 500 may have a chip-to-chip (C2C) structure. At least one upper chip (including a cell region) and a lower chip (including a peripheral circuit region PERI) may be manufactured separately. The at least one upper chip and the lower chip may be connected to each other by a bonding process to form the C2C structure. For example, the bonding process may involve electrically or physically connecting a bonding metal pattern formed on an uppermost metal layer of the upper chip to a bonding metal pattern formed in an uppermost metal layer of the lower chip. For example, in a case in which the bonding metal patterns are formed of copper (Cu), the bonding method may be a Cu-Cu bonding method. Alternatively, the bonding metal patterns may be formed of aluminum (Al) or tungsten (W).

The memory device 500 may include the at least one upper chip including the cell region. For example, as illustrated in FIG. 19, the memory device 500 may include two upper chips. However, the number of the upper chips is not limited thereto. In the case in which the memory device 500 includes the two upper chips, a first upper chip including a first cell region CELL1, a second upper chip including a second cell region CELL2 and the lower chip including the peripheral circuit region PERI may be manufactured separately, and then, the first upper chip, the second upper chip and the lower chip may be connected to each other by the bonding method to manufacture the memory device 500. The first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on before each of the first and second upper chips is turned over. In other words, an upper portion of the lower chip may mean an upper portion defined based on a +Z-axis direction, and the upper portion of each of the first and second upper chips may mean an upper portion defined based on a -Z-axis direction in FIG. 19. However, embodiments are not limited thereto. In certain embodiments, one of the first upper chip and the second upper chip may be turned over and then may be connected to a corresponding chip by the bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate band a plurality of circuit elements 620a, 620b and 620c formed on the first substrate 610. An interlayer insulating layer 615 including one or more insulating layers may be provided on the plurality of circuit elements 620a, 620b and 620c, and a plurality of metal lines electrically connected to the plurality of circuit elements 620a, 620b and 620c may be provided in the interlayer insulating layer 615. For example, the plurality of metal lines may include first metal lines 630a, 630b and 630c connected to the plurality of circuit elements 620a, 620b and 620c, and second metal lines 640a, 640b and 640c formed on the first metal lines 630a, 630b and 630c. The plurality of metal lines may be formed of at least one of various conductive materials. For example, the first metal lines 630a, 630b and 630c may be formed of tungsten having a relatively high electrical resistivity, and the second metal lines 640a, 640b and 640c may be formed of copper having a relatively low electrical resistivity.

The first metal lines 630a, 630b and 630c and the second metal lines 640a, 640b and 640c are illustrated and described in the present embodiments. However, embodiments are not limited thereto. In certain embodiments, at least one or more additional metal lines may further be formed on the second metal lines 640a, 640b and 640c. In this case, the second metal lines 640a, 640b and 640c may be formed of aluminum, and at least some of the additional metal lines formed on the second metal lines 640a, 640b and 640c may be formed of copper having an electrical resistivity lower than that of aluminum of the second metal lines 640a, 640b and 640c.

The interlayer insulating layer 615 may be disposed on the first substrate 610 and may include an insulating material such as silicon oxide and/or silicon nitride.

Each of the first and second cell regions CELL1 and CELL2 may include at least one memory block. The first cell region CELL1 may include a second substrate 710 and a common source line 720. A plurality of word lines 730 (731 to 738) may be stacked on the second substrate 710 in a direction (i.e., the Z-axis direction) perpendicular to a top surface of the second substrate 710. String selection lines and a ground selection line may be disposed on and under the word lines 730, and the plurality of word lines 730 may be disposed between the string selection lines and the ground selection line. Likewise, the second cell region CELL2 may include a third substrate 810 and a common source line 820, and a plurality of word lines 830 (831 to 838) may be stacked on the third substrate 810 in a direction (i.e., the Z-axis direction) perpendicular to a top surface of the third substrate 810. Each of the second substrate 710 and the third substrate 810 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CELL1 and CELL2.

In some embodiments, as illustrated in a region ‘A1’, the channel structure CH may be provided in the bit line bonding region BLBA and may extend in the direction perpendicular to the top surface of the second substrate 710 to penetrate the word lines 730, the string selection lines, and the ground selection line. The channel structure CH may include a data storage layer, a channel layer, and a filling insulation layer. The channel layer may be electrically connected to a first metal line 750c and a second metal line 760c in the bit line bonding region BLBA. For example, the second metal line 760c may be a bit line and may be connected to the channel structure CH through the first metal line 750c. The bit line 760c may extend in a first direction (e.g., a Y-axis direction) parallel to the top surface of the second substrate 710.

In some embodiments, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 710 to penetrate the common source line 720 and lower word lines 731 and 732. The lower channel LCH may include a data storage layer, a channel layer, and a filling insulation layer and may be connected to the upper channel UCH. The upper channel UCH may penetrate upper word lines 733 to 738. The upper channel UCH may include a data storage layer, a channel layer, and a filling insulation layer, and the channel layer of the upper channel UCH may be electrically connected to the first metal line 750c and the second metal line 760c. As a length of a channel increases, due to characteristics of manufacturing processes, it may be difficult to form a channel having a substantially uniform width. The memory device 500 according to the present embodiments may include a channel having improved width uniformity due to the lower channel LCH and the upper channel UCH which are formed by the processes performed sequentially.

In the case in which the channel structure CH includes the lower channel LCH and the upper channel UCH as illustrated in the region ‘A2’, a word line located near to a boundary between the lower channel LCH and the upper channel UCH may be a dummy word line. For example, the word lines 732 and 733 adjacent to the boundary between the lower channel LCH and the upper channel UCH may be the dummy word lines. In this case, data may not be stored in memory cells connected to the dummy word line. Alternatively, the number of pages corresponding to the memory cells connected to the dummy word line may be less than the number of pages corresponding to the memory cells connected to a general word line. A level of a voltage applied to the dummy word line may be different from a level of a voltage applied to the general word line, and thus it is possible to reduce an influence of a non-uniform channel width between the lower and upper channels LCH and UCH on an operation of the memory device 500.

Meanwhile, the number of the lower word lines 731 and 732 penetrated by the lower channel LCH is less than the number of the upper word lines 733 to 738 penetrated by the upper channel UCH in the region ‘A2’. However, embodiments are not limited thereto. In certain embodiments, the number of the lower word lines penetrated by the lower channel LCH may be equal to or more than the number of the upper word lines penetrated by the upper channel UCH. In addition, structural features and connection relation of the channel structure CH disposed in the second cell region CELL2 may be substantially the same as those of the channel structure CH disposed in the first cell region CELL1.

In the bit line bonding region BLBA, a first through-electrode THV1 may be provided in the first cell region CELL1, and a second through-electrode THV2 may be provided in the second cell region CELL2. As illustrated in FIG. 19, the first through-electrode THV1 may penetrate the common source line 720 and the plurality of word lines 730. In certain embodiments, the first through-electrode THV1 may further penetrate the second substrate 710. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some embodiments, the first through-electrode THV1 and the second through-electrode THV2 may be electrically connected to each other through a first through-metal pattern 772d and a second through-metal pattern 872d. The first through-metal pattern 772d may be formed at a bottom end of the first upper chip including the first cell region CELL1, and the second through-metal pattern 872d may be formed at a top end of the second upper chip including the second cell region CELL2. The first through-electrode THV1 may be electrically connected to the first metal line 750c and the second metal line 760c. A lower via 771d may be formed between the first through-electrode THV1 and the first through-metal pattern 772d, and an upper via 871d may be formed between the second through-electrode THV2 and the second through-metal pattern 872d. The first through-metal pattern 772d and the second through-metal pattern 872d may be connected to each other by the bonding method.

In addition, in the bit line bonding region BLBA, an upper metal pattern 652 may be formed in an uppermost metal layer of the peripheral circuit region PERI, and an upper metal pattern 792 having the same shape as the upper metal pattern 652 may be formed in an uppermost metal layer of the first cell region CELL1. The upper metal pattern 792 of the first cell region CELL1 and the upper metal pattern 652 of the peripheral circuit region PERI may be electrically connected to each other by the bonding method. In the bit line bonding region BLBA, the bit line 760c may be electrically connected to a page buffer included in the peripheral circuit region PERI. For example, some of the circuit elements 620c of the peripheral circuit region PERI may constitute the page buffer, and the bit line 760c may be electrically connected to the circuit elements 620c constituting the page buffer through an upper bonding metal pattern 770c of the first cell region CELL1 and an upper bonding metal pattern 670c of the peripheral circuit region PERI.

Referring continuously to FIG. 19, in the word line bonding region WLBA, the word lines 730 of the first cell region CELL1 may extend in a second direction (e.g., an X-axis direction) parallel to the top surface of the second substrate 710 and may be connected to a plurality of cell contact plugs 740 (741 to 747). First metal lines 750b and second metal lines 760b may be sequentially connected onto the cell contact plugs 740 connected to the word lines 730. In the word line bonding region WLBA, the cell contact plugs 740 may be connected to the peripheral circuit region PERI through upper bonding metal patterns 770b of the first cell region CELL1 and upper bonding metal patterns 670b of the peripheral circuit region PERI.

The cell contact plugs 740 may be electrically connected to a row decoder included in the peripheral circuit region PERI. For example, some of the circuit elements 620b of the peripheral circuit region PERI may constitute the row decoder, and the cell contact plugs 740 may be electrically connected to the circuit elements 620b constituting the row decoder through the upper bonding metal patterns 770b of the first cell region CELL1 and the upper bonding metal patterns 670b of the peripheral circuit region PERI. In some embodiments, an operating voltage of the circuit elements 620b constituting the row decoder may be different from an operating voltage of the circuit elements 620c constituting the page buffer. For example, the operating voltage of the circuit elements 620c constituting the page buffer may be greater than the operating voltage of the circuit elements 620b constituting the row decoder.

Likewise, in the word line bonding region WLBA, the word lines 830 of the second cell region CELL2 may extend in the second direction (e.g., the X-axis direction) parallel to the top surface of the third substrate 810 and may be connected to a plurality of cell contact plugs 840 (841 to 847). The cell contact plugs 840 may be connected to the peripheral circuit region PERI through an upper metal pattern of the second cell region CELL2 and lower and upper metal patterns and a cell contact plug 348 of the first cell region CELL1.

In the word line bonding region WLBA, the upper bonding metal patterns 770b may be formed in the first cell region CELL1, and the upper bonding metal patterns 670b may be formed in the peripheral circuit region PERI. The upper bonding metal patterns 770b of the first cell region CELL1 and the upper bonding metal patterns 670b of the peripheral circuit region PERI may be electrically connected to each other by the bonding method. The upper bonding metal patterns 770b and the upper bonding metal patterns 670b may be formed of aluminum, copper, or tungsten.

In the external pad bonding region PA, a lower metal pattern 771e may be formed in a lower portion of the first cell region CELL1, and an upper metal pattern 872a may be formed in an upper portion of the second cell region CELL2. The lower metal pattern 771e of the first cell region CELL1 and the upper metal pattern 872a of the second cell region CELL2 may be connected to each other by the bonding method in the external pad bonding region PA. Likewise, an upper metal pattern 772a may be formed in an upper portion of the first cell region CELL1, and an upper metal pattern 672a may be formed in an upper portion of the peripheral circuit region PERI. The upper metal pattern 772a of the first cell region CELL1 and the upper metal pattern 672a of the peripheral circuit region PERI may be connected to each other by the bonding method.

Common source line contact plugs 780 and 880 may be disposed in the external pad bonding region PA. The common source line contact plugs 780 and 880 may be formed of a conductive material such as a metal, a metal compound, and/or doped polysilicon. The common source line contact plug 780 of the first cell region CELL1 may be electrically connected to the common source line 720, and the common source line contact plug 880 of the second cell region CELL2 may be electrically connected to the common source line 820. A first metal line 750a and a second metal line 760a may be sequentially stacked on the common source line contact plug 780 of the first cell region CELL1, and a first metal line 850a and a second metal line 860a may be sequentially stacked on the common source line contact plug 880 of the second cell region CELL2.

Input/output pads 605, 805 and 806 may be disposed in the external pad bonding region PA. Referring to FIG. 19, a lower insulating layer 611 may cover a bottom surface of the first substrate 610, and a first input/output pad 605 may be formed on the lower insulating layer 611. The first input/output pad 605 may be connected to at least one of a plurality of the circuit elements 620a disposed in the peripheral circuit region PERI through a first input/output contact plug 603 and may be separated from the first substrate 610 by the lower insulating layer 611. In addition, a side insulating layer may be disposed between the first input/output contact plug 603 and the first substrate 610 to electrically isolate the first input/output contact plug 603 from the first substrate 610.

An upper insulating layer 801 covering a top surface of the third substrate 810 may be formed on the third substrate 810. A second input/output pad 805 and/or a third input/output pad 806 may be disposed on the upper insulating layer 801. The second input/output pad 805 may be connected to at least one of the plurality of circuit elements 620a disposed in the peripheral circuit region PERI through second input/output contact plugs 803 and 703, and the third input/output pad 806 may be connected to at least one of the plurality of circuit elements 620a disposed in the peripheral circuit region PERI through third input/output contact plugs 804 and 704.

In some embodiments, the third substrate 810 may not be disposed in a region in which the input/output contact plug is disposed. For example, as illustrated in a region ‘B’, the third input/output contact plug 804 may be separated from the third substrate 810 in a direction parallel to the top surface of the third substrate 810 and may penetrate an interlayer insulating layer 815 of the second cell region CELL2 so as to be connected to the third input/output pad 806. In this case, the third input/output contact plug 804 may be formed by at least one of various processes.

In some embodiments, as illustrated in a region ‘B1’, the third input/output contact plug 804 may extend in a third direction (e.g., the Z-axis direction), and a diameter of the third input/output contact plug 804 may become progressively greater toward the upper insulating layer 801. In other words, a diameter of the channel structure CH described in the region ‘A1’ may become progressively less toward the upper insulating layer 801, but the diameter of the third input/output contact plug 804 may become progressively greater toward the upper insulating layer 801. For example, the third input/output contact plug 804 may be formed after the second cell region CELL2 and the first cell region CELL1 are bonded to each other by the bonding method.

In certain embodiments, as illustrated in a region ‘B2’, the third input/output contact plug 804 may extend in the third direction (e.g., the Z-axis direction), and a diameter of the third input/output contact plug 804 may become progressively less toward the upper insulating layer 801. In other words, like the channel structure CH, the diameter of the third input/output contact plug 804 may become progressively less toward the upper insulating layer 801. For example, the third input/output contact plug 804 may be formed together with the cell contact plugs 840 before the second cell region CELL2 and the first cell region CELL1 are bonded to each other.

In certain embodiments, the input/output contact plug may overlap with the third substrate 810. For example, as illustrated in a region ‘C’, the second input/output contact plug 803 may penetrate the interlayer insulating layer 815 of the second cell region CELL2 in the third direction (e.g., the Z-axis direction) and may be electrically connected to the second input/output pad 805 through the third substrate 810. In this case, a connection structure of the second input/output contact plug 803 and the second input/output pad 805 may be realized by various methods.

In some embodiments, as illustrated in a region ‘C1’, an opening 808 may be formed to penetrate the third substrate 810, and the second input/output contact plug 803 may be connected directly to the second input/output pad 805 through the opening 808 formed in the third substrate 810. In this case, as illustrated in the region ‘C1’, a diameter of the second input/output contact plug 803 may become progressively greater toward the second input/output pad 805. However, embodiments are not limited thereto, and in certain embodiments, the diameter of the second input/output contact plug 803 may become progressively less toward the second input/output pad 805.

In certain embodiments, as illustrated in a region ‘C2’, the opening 808 penetrating the third substrate 810 may be formed, and a contact 807 may be formed in the opening 808. An end of the contact 807 may be connected to the second input/output pad 805, and another end of the contact 807 may be connected to the second input/output contact plug 803. Thus, the second input/output contact plug 803 may be electrically connected to the second input/output pad 805 through the contact 807 in the opening 808. In this case, as illustrated in the region ‘C2’, a diameter of the contact 807 may become progressively greater toward the second input/output pad 805, and a diameter of the second input/output contact plug 803 may become progressively less toward the second input/output pad 805. For example, the second input/output contact plug 803 may be formed together with the cell contact plugs 840 before the second cell region CELL2 and the first cell region CELL1 are bonded to each other, and the contact 807 may be formed after the second cell region CELL2 and the first cell region CELL1 are bonded to each other.

In certain embodiments illustrated in a region ‘C3’, a stopper 809 may further be formed on a bottom end of the opening 808 of the third substrate 810, as compared with the embodiments of the region ‘C2’. The stopper 809 may be a metal line formed in the same layer as the common source line 820. Alternatively, the stopper 809 may be a metal line formed in the same layer as at least one of the word lines 830. The second input/output contact plug 803 may be electrically connected to the second input/output pad 805 through the contact 807 and the stopper 809.

Like the second and third input/output contact plugs 803 and 804 of the second cell region CELL2, a diameter of each of the second and third input/output contact plugs 703 and 704 of the first cell region CELL1 may become progressively less toward the lower metal pattern 771e or may become progressively greater toward the lower metal pattern 771e.

Meanwhile, in some embodiments, a slit 811 may be formed in the third substrate 810. For example, the slit 811 may be formed at a certain position of the external pad bonding region PA. For example, as illustrated in a region ‘D’, the slit 811 may be located between the second input/output pad 805 and the cell contact plugs 840 when viewed in a plan view. Alternatively, the second input/output pad 805 may be located between the slit 811 and the cell contact plugs 840 when viewed in a plan view.

In some embodiments, as illustrated in a region ‘D1’, the slit 811 may be formed to penetrate the third substrate 810. For example, the slit 811 may be used to prevent the third substrate 810 from being finely cracked when the opening 808 is formed. However, embodiments are not limited thereto, and in certain embodiments, the slit 811 may be formed to have a depth ranging from about 60% to about 70% of a thickness of the third substrate 810.

In certain embodiments, as illustrated in a region ‘D2’, a conductive material 812 may be formed in the slit 811. For example, the conductive material 812 may be used to discharge a leakage current occurring in driving of the circuit elements in the external pad bonding region PA to the outside. In this case, the conductive material 812 may be connected to an external ground line.

In certain embodiments, as illustrated in a region ‘D3’, an insulating material 813 may be formed in the slit 811. For example, the insulating material 813 may be used to electrically isolate the second input/output pad 805 and the second input/output contact plug 803 disposed in the external pad bonding region PA from the word line bonding region WLBA. Since the insulating material 813 is formed in the slit 811, it is possible to prevent a voltage provided through the second input/output pad 805 from affecting a metal layer disposed on the third substrate 810 in the word line bonding region WLBA.

Meanwhile, in certain embodiments, the first to third input/output pads 605, 805 and 806 may be selectively formed. For example, the memory device 500 may be realized to include only the first input/output pad 605 disposed on the first substrate 610, to include only the second input/output pad 805 disposed on the third substrate 810, or to include only the third input/output pad 806 disposed on the upper insulating layer 801.

In some embodiments, at least one of the second substrate 710 of the first cell region CELL1 or the third substrate 810 of the second cell region CELL2 may be used as a sacrificial substrate and may be completely or partially removed before or after a bonding process. An additional layer may be stacked after the removal of the substrate. For example, the second substrate 710 of the first cell region CELL1 may be removed before or after the bonding process of the peripheral circuit region PERI and the first cell region CELL1, and then, an insulating layer covering a top surface of the common source line 720 or a conductive layer for connection may be formed. Likewise, the third substrate 810 of the second cell region CELL2 may be removed before or after the bonding process of the first cell region CELL1 and the second cell region CELL2, and then, the upper insulating layer 801 covering a top surface of the common source line 820 or a conductive layer for connection may be formed.

The memory cell array 100 of FIG. 1 may be disposed on the first cell region CELL1 and/or the second cell region CELL2. The peripheral circuit 200 of FIG. 1 may be disposed on the peripheral region PERI.

The first, second, third and fourth extension line L1, L2, L3 and L4 may be formed in a metal layer between the second metal line 760c and the upper bonding metal 770c in the first cell region CELL1. In addition, the first, second, third and fourth extension line L1’, L2’, L3’ and L4’ may be formed in a metal layer of the metal lines 630c, 640c in the peripheral region PERI.

Some of the circuit elements 620c of the peripheral circuit region PERI may constitute the page buffer decoder and the page buffer driver.

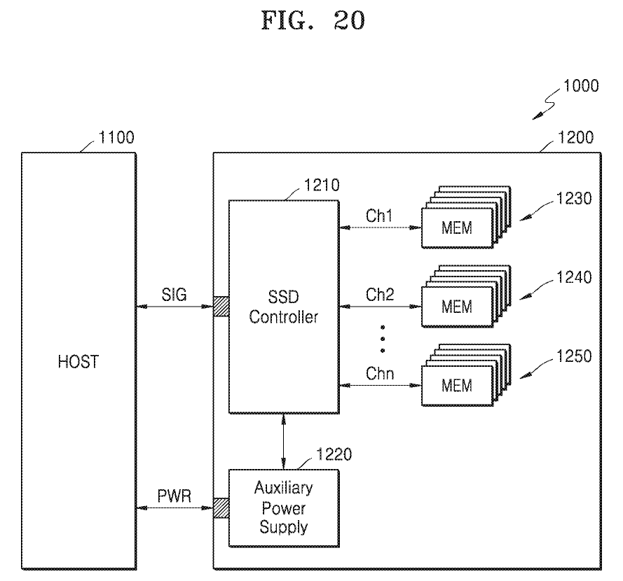

FIG. 20 is a view illustrating a solid-state drive (SSD) 1200 including memory devices 1230, 1240, and 1250 according to an embodiment.

Referring to FIG. 20, an SSD system 1000 may include a host 1100 and the SSD 1200. The SSD 1200 exchanges signals with the host 1100 through a signal connector and receives power through a power connector. The SSD 1200 may include an SSD controller 1210, an auxiliary power supply 1220, and the memory devices 1230, 1240, and 1250. The memory devices 1230, 1240, and 1250 may each be a vertically stacked NAND flash memory device. In this case, the SSD 1200 may be implemented using the embodiments described above with reference to FIGS. 1 to 19.

In one or more embodiments of the disclosure, a memory device may include: a first sub-plane including a plurality of memory cells connected to a plurality of first bit lines; a second sub-plane including a plurality of memory cells connected to a plurality of second bit lines; first page buffers and second page buffers each configured to sense data from memory cells through a corresponding bit line; a data input/output circuit configured to transmit data through a plurality of data pins; a first page buffer driver configured to provide data from the first page buffers to the data input/output circuit; and a second page buffer driver configured to provide data from the second page buffers to the data input/output circuit, wherein a first subset of the plurality of first bit lines may be connected to a first subset of the first page buffers, a second subset of the plurality of first bit lines may be connected to a first subset of the second page buffers, a first subset of the plurality of second bit lines may be connected to a second subset of the first page buffers, and a second subset of the plurality of second bit lines may be connected to a second subset of the second page buffers.

During a read operation performed on the plurality of memory cells included in the first sub-plane, the first page buffer driver may be configured to provide, to the data input/output circuit, data sensed by the subset of the first page buffers through the first subset of the plurality of first bit lines, and the second page buffer driver may be configured to provide, to the data input/output circuit, data sensed by the first subset of the second page buffers through the second subset of the plurality of first bit lines.

During a read operation performed on the plurality of memory cells included in the second sub-plane, the first page buffer driver may be configured to provide, to the data input/output circuit, data sensed by the second subset of the first page buffers through the first subset of the plurality of second bit lines, and the second page buffer driver may be configured to provide, to the data input/output circuit, data sensed by the second subset of the second page buffers through the second subset of the plurality of second bit lines.

The first sub-plane and the second sub-plane may be in a first region, the first page buffers and the second page buffers may be in a second region that may be vertically aligned with and positioned above or below the first region, the first sub-plane and the first page buffers vertically overlap each other, and the second sub-plane and the second page buffers vertically overlap each other.

The plurality of first bit lines may be apart from the plurality of second bit lines in a first horizontal direction and extend in a first wiring layer in the first horizontal direction, and the second subset of the plurality of first bit lines may be connected to a first line that extends in a second wiring layer within the first region from a region vertically overlapping the first page buffers to a region vertically overlapping the subset of the second page buffers.

The first subset of the plurality of second bit lines may be connected to a second line that extends in the second wiring layer from a region vertically overlapping the second page buffers to a region vertically overlapping the second subset of the first page buffers.

The second subset of the plurality of first bit lines may be connected to a third line that extends in a third wiring layer within the second region from a region vertically overlapping the first page buffers to a region vertically overlapping the subset of the second page buffers.

The first subset of the plurality of second bit lines may be connected a fourth line that extends in the third wiring layer from a region vertically overlapping the second page buffers to a region vertically overlapping the second subset of the first page buffers.

In one or more embodiments of the disclosure, a memory device may include: a first sub-plane including a plurality of memory cells; a second sub-plane including a plurality of memory cells; a first bit line group including a plurality of first bit lines that may be connected to the first sub-plane, extend in a first horizontal direction, and may be arranged in a second horizontal direction perpendicular to the first horizontal direction; a second bit line group including a plurality of second bit lines that may be connected to the second sub-plane, extend in the first horizontal direction, and may be arranged in the second horizontal direction, the second bit line group being apart from the first bit line group in the first horizontal direction by a bit line cut region; a first extension line group including a plurality of first extension lines that may be connected to a first subset of the plurality of second bit lines and extend across the bit line cut region from a region vertically overlapping the first subset of the plurality of second bit lines to a region vertically overlapping a first subset of the plurality of first bit lines; a second extension line group including a plurality of second extension lines that may be connected to a second subset of the plurality of first bit lines and extend across the bit line cut region from a region vertically overlapping the second subset of the plurality of first bit lines to a region vertically overlapping a second subset of the plurality of second bit lines; and a page buffer circuit including page buffers connected to the first bit line group and the second bit line group through the first extension line group and the second extension line group.

Lengths of the plurality of first bit lines may be equal to each other, and lengths of the plurality of second bit lines may be equal to each other.

Among the plurality of first bit lines, N first bit lines each having a first length and N first bit lines each having a second length may be alternately arranged in the second horizontal direction, where N refers to a natural number.

The page buffer circuit may include first page buffers and second page buffers each configured to sense data from memory cells through a corresponding bit line; wherein the memory device further may include: a data input/output circuit configured to transmit data through a plurality of data pins; a first page buffer driver configured to provide data from the first page buffers to the data input/output circuit; and a second page buffer driver configured to provide data from the second page buffers to the data input/output circuit, wherein the first subset of the plurality of first bit lines may be connected to a subset of the first page buffers, the second subset of the plurality of first bit lines may be connected to a subset of the second page buffers, the first subset of the plurality of second bit lines may be connected to a second subset of the first page buffers, and the second subset of the plurality of second bit lines may be connected to a second subset of the second page buffers.

The first sub-plane and the second sub-plane may be in a first region, first page buffers and second page buffers may be in a second region that may be vertically aligned with and positioned above or below the first region, the first sub-plane and the first page buffers vertically overlap each other, and the second sub-plane and the second page buffers vertically overlap each other.

The plurality of first bit lines may be apart from the plurality of second bit lines in the first horizontal direction and extend in a first wiring layer in the first horizontal direction, and the second subset of the plurality of first bit lines may be connected to a first line that extends in a second wiring layer within the first region from a region vertically overlapping the first page buffers to a region vertically overlapping a subset of the second page buffers.

The first subset of the plurality of second bit lines may be connected to a second line that extends in the second wiring layer from a region vertically overlapping the second page buffers to a region vertically overlapping a second subset of the first page buffers.

In one or more embodiments of the disclosure, a memory device may include: a plurality of sub-planes connected to a plurality of bit line groups including a first bit line group and a second bit line group, each of the first bit line group and the second bit line group including a plurality of bit lines; a plurality of page buffer groups including a first page buffer group and a second page buffer group, each of the first page buffer group and the second page buffer group including a plurality of page buffers each configured to sense data through a corresponding bit line; a data input/output circuit configured to transmit data through a plurality of data pins; and a plurality of page buffer drivers each configured to provide data sensed by a page buffer group to the data input/output circuit, wherein a first number of first bit lines included in the first bit line group may be connected to a first number of first page buffers included in the first page buffer group, a second number of first bit lines included in the first bit line group may be connected to a second number of second page buffers included in the second page buffer group, a third number of second bit lines included in the second bit line group may be connected to a third number of first page buffers included in the first page buffer group, and a fourth number of second bit lines included in the second bit line group may be connected to a fourth number of second page buffers included in the second page buffer group.

During a read operation performed on memory cells included in a first sub-plane of the plurality of sub-planes, a first page buffer driver of the plurality of page buffer drivers may be configured to provide, to the data input/output circuit, data sensed by the first number of first page buffers through the first number of first bit lines, and a second page buffer driver of the plurality of page buffer drivers may be configured to provide, to the data input/output circuit, data sensed by the second number of second page buffers through the second number of first bit lines.

During a read operation performed on memory cells included in a second sub-plane of the plurality of sub-planes, the first page buffer driver may be configured to provide, to the data input/output circuit, data sensed by the third number of first page buffers through the third number of second bit lines, and the second page buffer driver may be configured to provide, to the data input/output circuit, data sensed by the fourth number of second page buffers through the fourth number of second bit lines.

The plurality of sub-planes may be in a first region, and the plurality of page buffer groups, the data input/output circuit, and the plurality of page buffer drivers may be in a second region that may be vertically disposed on the first region.

The first bit lines and the second bit lines may be apart from each other in a first horizontal direction and extend in a first wiring layer in the first horizontal direction, and the second number of first bit lines may be connected to a first line that extends in a second wiring layer within the first region from a region vertically overlapping the first page buffers to a region vertically overlapping the second number of second page buffers.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. A memory device comprising:
a first sub-plane comprising a plurality of memory cells connected to a plurality of first bit lines;
a second sub-plane comprising a plurality of memory cells connected to a plurality of second bit lines;
first page buffers and second page buffers each configured to sense data from memory cells through a corresponding bit line;
a data input/output circuit configured to transmit data through a plurality of data pins;
a first page buffer driver configured to provide data from the first page buffers to the data input/output circuit; and
a second page buffer driver configured to provide data from the second page buffers to the data input/output circuit,
wherein a first subset of the plurality of first bit lines is connected to a first subset of the first page buffers, a second subset of the plurality of first bit lines is connected to a first subset of the second page buffers, a first subset of the plurality of second bit lines is connected to a second subset of the first page buffers, and a second subset of the plurality of second bit lines is connected to a second subset of the second page buffers.

2. The memory device of claim 1, wherein, during a read operation performed on the plurality of memory cells included in the first sub-plane,
the first page buffer driver is configured to provide, to the data input/output circuit, data sensed by the subset of the first page buffers through the first subset of the plurality of first bit lines, and
the second page buffer driver is configured to provide, to the data input/output circuit, data sensed by the first subset of the second page buffers through the second subset of the plurality of first bit lines.

3. The memory device of claim 1, wherein, during a read operation performed on the plurality of memory cells included in the second sub-plane,
the first page buffer driver is configured to provide, to the data input/output circuit, data sensed by the second subset of the first page buffers through the first subset of the plurality of second bit lines, and
the second page buffer driver is configured to provide, to the data input/output circuit, data sensed by the second subset of the second page buffers through the second subset of the plurality of second bit lines.

4. The memory device of claim 1, wherein the first sub-plane and the second sub-plane are in a first region,
the first page buffers and the second page buffers are in a second region that is vertically aligned with and positioned below the first region,
the first sub-plane and the first page buffers vertically overlap each other, and
the second sub-plane and the second page buffers vertically overlap each other.

5. The memory device of claim 4, wherein the plurality of first bit lines is apart from the plurality of second bit lines in a first horizontal direction and extend in a first wiring layer in the first horizontal direction, and
the second subset of the plurality of first bit lines is connected to a first line that extends in a second wiring layer within the first region from a region vertically overlapping the first page buffers to a region vertically overlapping the subset of the second page buffers.

6. The memory device of claim 5, wherein the first subset of the plurality of second bit lines is connected to a second line that extends in the second wiring layer from a region vertically overlapping the second page buffers to a region vertically overlapping the second subset of the first page buffers.

7. The memory device of claim 4, wherein the second subset of the plurality of first bit lines is connected to a third line that extends in a third wiring layer within the second region from a region vertically overlapping the first page buffers to a region vertically overlapping the subset of the second page buffers.

8. The memory device of claim 7, wherein the first subset of the plurality of second bit lines is connected a fourth line that extends in the third wiring layer from a region vertically overlapping the second page buffers to a region vertically overlapping the second subset of the first page buffers.

9. A memory device comprising:
a first sub-plane comprising a plurality of memory cells;
a second sub-plane comprising a plurality of memory cells;
a first bit line group comprising a plurality of first bit lines that are connected to the first sub-plane, extend in a first horizontal direction, and are arranged in a second horizontal direction perpendicular to the first horizontal direction;
a second bit line group comprising a plurality of second bit lines that are connected to the second sub-plane, extend in the first horizontal direction, and are arranged in the second horizontal direction, the second bit line group being apart from the first bit line group in the first horizontal direction by a bit line cut region;
a first extension line group comprising a plurality of first extension lines that are connected to a first subset of the plurality of second bit lines and extend across the bit line cut region from a region vertically overlapping the first subset of the plurality of second bit lines to a region vertically overlapping a first subset of the plurality of first bit lines;
a second extension line group comprising a plurality of second extension lines that are connected to a second subset of the plurality of first bit lines and extend across the bit line cut region from a region vertically overlapping the second subset of the plurality of first bit lines to a region vertically overlapping a second subset of the plurality of second bit lines; and
a page buffer circuit comprising page buffers connected to the first bit line group and the second bit line group through the first extension line group and the second extension line group.

10. The memory device of claim 9, wherein lengths of the plurality of first bit lines are equal to each other, and
lengths of the plurality of second bit lines are equal to each other.

11. The memory device of claim 9, wherein, among the plurality of first bit lines, N first bit lines each having a first length and N first bit lines each having a second length are alternately arranged in the second horizontal direction, where N refers to a natural number.

12. The memory device of claim 9, wherein the page buffer circuit comprises first page buffers and second page buffers each configured to sense data from memory cells through a corresponding bit line;
wherein the memory device further comprises:
a data input/output circuit configured to transmit data through a plurality of data pins;
a first page buffer driver configured to provide data from the first page buffers to the data input/output circuit; and
a second page buffer driver configured to provide data from the second page buffers to the data input/output circuit,
wherein the first subset of the plurality of first bit lines is connected to a subset of the first page buffers, the second subset of the plurality of first bit lines is connected to a subset of the second page buffers, the first subset of the plurality of second bit lines is connected to a second subset of the first page buffers, and the second subset of the plurality of second bit lines is connected to a second subset of the second page buffers.

13. The memory device of claim 9, wherein the first sub-plane and the second sub-plane are in a first region,
first page buffers and second page buffers are in a second region that is vertically aligned with and positioned below the first region,
the first sub-plane and the first page buffers vertically overlap each other, and
the second sub-plane and the second page buffers vertically overlap each other.

14. The memory device of claim 13, wherein the plurality of first bit lines is apart from the plurality of second bit lines in the first horizontal direction and extend in a first wiring layer in the first horizontal direction, and
the second subset of the plurality of first bit lines is connected to a first line that extends in a second wiring layer within the first region from a region vertically overlapping the first page buffers to a region vertically overlapping a subset of the second page buffers.

15. The memory device of claim 14, wherein the first subset of the plurality of second bit lines is connected to a second line that extends in the second wiring layer from a region vertically overlapping the second page buffers to a region vertically overlapping a second subset of the first page buffers.

16. A memory device comprising:
a plurality of sub-planes connected to a plurality of bit line groups comprising a first bit line group and a second bit line group, each of the first bit line group and the second bit line group comprising a plurality of bit lines;
a plurality of page buffer groups comprising a first page buffer group and a second page buffer group, each of the first page buffer group and the second page buffer group comprising a plurality of page buffers each configured to sense data through a corresponding bit line;
a data input/output circuit configured to transmit data through a plurality of data pins; and
a plurality of page buffer drivers each configured to provide data sensed by the plurality of page buffer groups to the data input/output circuit,
wherein a first number of first bit lines included in the first bit line group is connected to a first number of first page buffers included in the first page buffer group, a second number of first bit lines included in the first bit line group is connected to a second number of second page buffers included in the second page buffer group, a third number of second bit lines included in the second bit line group is connected to a third number of first page buffers included in the first page buffer group, and a fourth number of second bit lines included in the second bit line group is connected to a fourth number of second page buffers included in the second page buffer group.

17. The memory device of claim 16, wherein, during a read operation performed on memory cells included in a first sub-plane of the plurality of sub-planes,
a first page buffer driver of the plurality of page buffer drivers is configured to provide, to the data input/output circuit, data sensed by the first number of first page buffers through the first number of first bit lines, and
a second page buffer driver of the plurality of page buffer drivers is configured to provide, to the data input/output circuit, data sensed by the second number of second page buffers through the second number of first bit lines.

18. The memory device of claim 17, wherein, during a read operation performed on memory cells included in a second sub-plane of the plurality of sub-planes,
the first page buffer driver is configured to provide, to the data input/output circuit, data sensed by the third number of first page buffers through the third number of second bit lines, and
the second page buffer driver is configured to provide, to the data input/output circuit, data sensed by the fourth number of second page buffers through the fourth number of second bit lines.

19. The memory device of claim 18, wherein the plurality of sub-planes are in a first region, and
the plurality of page buffer groups, the data input/output circuit, and the plurality of page buffer drivers are in a second region that is vertically disposed on the first region.

20. The memory device of claim 19, wherein the first bit lines and the second bit lines are apart from each other in a first horizontal direction and extend in a first wiring layer in the first horizontal direction, and
the second number of first bit lines is connected to a first line that extends in a second wiring layer within the first region from a region vertically overlapping the first page buffers to a region vertically overlapping the second number of second page buffers.
